(19) United States
(12) Patent Application Publication
(10) Pub. No.: US 2018/0186935 A1
(43) Pub. Date: Jul. 5, 2018

(54) POLYIMIDE FILM, ORGANIC ELECTROLUMINESCENT ELEMENT, TRANSPARENT ELECTRO-CONDUCTIVE LAMINATE, TOUCH PANEL, SOLAR CELL, AND DISPLAY DEVICE

(71) Applicant: JXTG NIPPON OIL & ENERGY CORPORATION, Tokyo (JP)

(72) Inventors: Shinichi KOMATSU, Tokyo (JP); Takaya MATSUMOTO, Tokyo (JP)

(73) Assignee: JXTG NIPPON OIL & ENERGY CORPORATION, Tokyo (JP)

(21) Appl. No.: 15/738,935

(22) PCT Filed: Jun. 21, 2016
(86) PCT No.: PCT/JP2016/068350

§ 371 Date: Dec. 21, 2017

(30) Foreign Application Priority Data
Jun. 30, 2015 (JP) 2015-131982

(51) Int. Cl. C08G 73/10; C08J 5/18; H01L 51/00; B32B 27/28

(52) U.S. Cl. CPC C08G 73/105; C08J 5/18; H01L 51/0097; B32B 27/281; C08J 2379/08; H01L 2251/5338; G06F 3/041; B32B 2307/412; B32B 2307/202; B32B 2379/08; B32B 2457/12; B32B 2457/20; B32B 2457/208; B32B 2250/02

(57) ABSTRACT

A polyimide film comprises a polyimide containing: a repeating unit (A) represented by a particular general formula: and a repeating unit (B) represented by a particular general formula, wherein a content ratio of the repeating unit (A) to a total amount of the repeating units (A) and (B) is 10 to 70% by mole, and the polyimide film has a linear expansion coefficient of 55 ppm/K or less, a tensile strength of 125 MPa or more, and a break elongation of 15% or more.

### TECHNICAL FIELD

The present invention relates to a polyimide film, an organic electroluminescent element, a transparent electro-conductive laminate, a touch panel, a solar cell, and a display device.

### BACKGROUND ART

Recently, in the field of, for example, display devices such as liquid-crystal displays and displays using organic electroluminescent elements, there have been demands for the development of a material which is utilized for substrates and the like of these displays, and which is a light and flexible material having a high light transmittance and a sufficiently high heat resistance like glass. In addition, as a material used for such glass substitute application or the like, attention has been focused on films made of light and flexible polyimide with high heat resistance.

As such a polyimide, for example, an aromatic polyimide (for example, trade name “Kapton” manufactured by DuPont) has been known. However, although such an aromatic polyimide has a sufficient flexibility and a high heat resistance, the polyimide is colored in brown and cannot be used in glass substitute application, optical application, and the like where light transmittance is necessary.

For this reason, recently, the development of alicyclic polyimides having sufficient light transmittances has been advanced for the uses in glass substitute application and the like. For example, International Publication No. WO2011/099518 (PTL 1) discloses a polyimide having a repeating unit represented by a particular general formula. Additionally, such a polyimide as described in PTL 1 has a sufficient light transmittance and a high heat resistance.

### CITATION LIST

### Patent Literature

[PTL 1] International Publication No. WO2011/099518

### SUMMARY OF INVENTION

### Technical Problem

However, PTL 1 does not describe the polyimide having a higher mechanical strength (toughness) based on tensile strength and break elongation, and also having a sufficiently low linear expansion coefficient.

The present invention has been made in view of the problems of the above-described conventional technique. An object of the present invention is to provide a polyimide film and an organic electroluminescent element using the same, the polyimide film being capable of having: a tensile strength and an elongation characteristic at higher levels in a well-balanced manner; a higher toughness based on the tensile strength and break elongation; a sufficiently low linear expansion coefficient; and the sufficiently high toughness and the sufficiently low linear expansion coefficient at higher levels in a well-balanced manner. Another object of the present invention is to provide a transparent electro-conductive laminate using the polyimide film as well as a touch panel, a solar cell, and a display device using the transparent electro-conductive laminate.

### Solution to Problem

The present inventors have conducted earnest study to achieve the above-described objects. As a result, the present inventors have found that when a polyimide film comprises a polyimide containing a repeating unit (A) represented by the following general formula (1) and a repeating unit (B) represented by the following general formula (2) such that a content ratio of the repeating unit (A) to a total amount of the repeating units (A) and (B) is 10 to 70% by mole, this enables the polyimide film to have: a tensile strength and an elongation characteristic (this property indicates a sufficient elongation until the film is broken) at higher levels in a well-balanced manner; a higher toughness based on the tensile strength and break elongation; a sufficiently low linear expansion coefficient; and the sufficiently high toughness and the sufficiently low linear expansion coefficient at higher levels in a well-balanced manner. This finding has led to the completion of the present invention.

Specifically, a polyimide film of the present invention comprises a polyimide containing:
a repeating unit (A) represented by the following general formula (1):

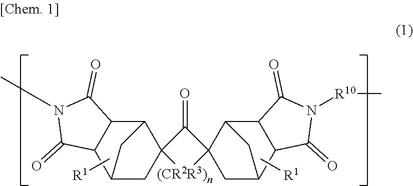

[in the formula (1), R¹, R², and R³ each independently represent one selected from the group consisting of a hydrogen atom, alkyl groups having 1 to 10 carbon atoms, and a fluorine atom, R¹⁰ represents a group represented by the following general formula (101):

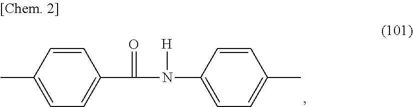

and n represents an integer of 0 to 12]; and
a repeating unit (B) represented by the following general formula (2):

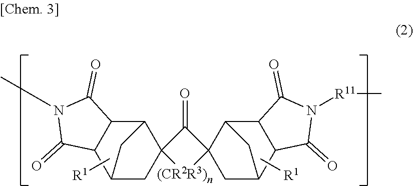

[in the formula (2), R¹, R², and R³ each independently represent one selected from the group consisting of a hydrogen atom, alkyl groups having 1 to 10 carbon atoms, and a fluorine atom, R¹¹ represents one selected from groups represented by the following general formulae (201) to (203):

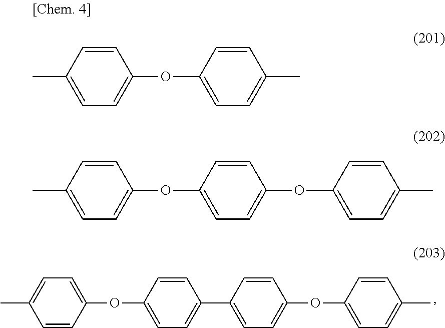

and n represents an integer of 0 to 12], wherein

a content ratio of the repeating unit (A) to a total amount of the repeating units (A) and (B) is 10 to 70% by mole, and

the polyimide film has a linear expansion coefficient of 55 ppm/K or less, a tensile strength of 125 MPa or more, and a break elongation of 15% or more.

In the polyimide film of the present invention, the content ratio of the repeating unit (A) to the total amount of the repeating units (A) and (B) is preferably 20 to 60% by mole.

An organic electroluminescent element of the present invention comprises the above-described polyimide film of the present invention.

Moreover, a transparent electro-conductive laminate of the present invention comprises:

the above-described polyimide film of the present invention; and

a thin film made of an electro-conductive material and stacked on the polyimide film.

Further, a touch panel, a solar cell, and a display device of the present invention each comprise the above-described transparent electro-conductive laminate of the present invention.

### Advantageous Effects of Invention

According to the present invention, it is possible to provide a polyimide film and an organic electroluminescent element using the same, the polyimide film being capable of having: a tensile strength and an elongation characteristic at higher levels in a well-balanced manner; a higher toughness based on the tensile strength and break elongation; a sufficiently low linear expansion coefficient; and the sufficiently high toughness and the sufficiently low linear expansion coefficient at higher levels in a well-balanced manner. According to the present invention, it is also possible to provide a transparent electro-conductive laminate using the polyimide film as well as a touch panel, a solar cell, and a display device using the transparent electro-conductive laminate.

### BRIEF DESCRIPTION OF DRAWINGS

FIG. 1 is a schematic longitudinal sectional view for illustrating a preferred embodiment of an organic electroluminescent element of the present invention.

FIG. 2 is a graph showing an infrared absorption spectrum (IR spectrum) of a polyimide film obtained in Example 1.

### DESCRIPTION OF EMBODIMENTS

Hereinafter, the present invention will be described in detail based on preferred embodiments thereof.

[Polyimide Film]

A polyimide film of the present invention comprises a polyimide containing:
a repeating unit (A) represented by the following general formula (1):

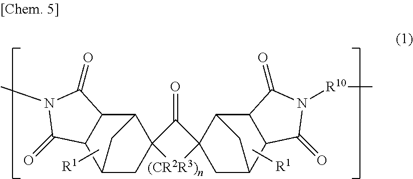

[in the formula (1), R¹, R², and R³ each independently represent one selected from the group consisting of a hydrogen atom, alkyl groups having 1 to 10 carbon atoms, and a fluorine atom, R¹⁰ represents a group represented by the following general formula (101):

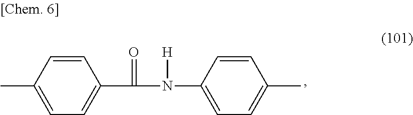

and n represents an integer of 0 to 12]; and
a repeating unit (B) represented by the following general formula (2):

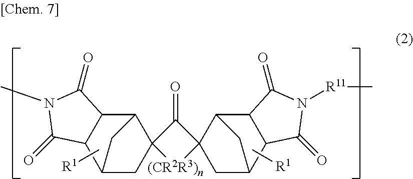

[in the formula (2), R¹, R², and R³ each independently represent one selected from the group consisting of a hydrogen atom, alkyl groups having 1 to 10 carbon atoms, and a fluorine atom, R¹¹ represents one selected from groups represented by the following general formulae (201) to (203):

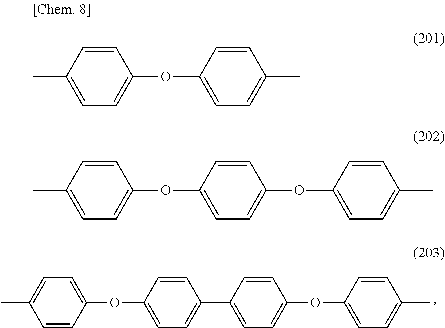

and n represents an integer of 0 to 12], wherein

a content ratio of the repeating unit (A) to a total amount of the repeating units (A) and (B) is 10 to 70% by mole, and

the polyimide film has a linear expansion coefficient of 55 ppm/K or less, a tensile strength of 125 MPa or more, and a break elongation of 15% or more.

In the repeating unit (A) of the polyimide according to the present invention, the alkyl group which can be selected as any one of R¹, R², and R³ in the general formula (1) is an alkyl group having 1 to 10 carbon atoms. If the number of carbon atoms exceeds 10, the glass transition temperature is lowered, so that a sufficiently high heat resistance cannot be achieved. In addition, the number of carbon atoms of the alkyl group which can be selected as any one of R¹, R², and R³ is preferably 1 to 6, more preferably 1 to 5, further preferably 1 to 4, and particularly preferably 1 to 3, from the viewpoint that the purification becomes easier. In addition, the alkyl group which can be selected as any one of R¹, R², and R³ may be linear or branched. Further, the alkyl group is more preferably a methyl group or an ethyl group from the viewpoint of ease of purification.

Furthermore, R¹, R², and R³ in the general formula (1) are more preferably each independently a hydrogen atom or an alkyl group having 1 to 10 carbon atoms, from the viewpoint that a higher heat resistance is obtained in the production of the polyimide. In particular, R¹, R², and R³ in the general formula (1) are more preferably each independently a hydrogen atom, a methyl group, an ethyl group, a n-propyl group, or an isopropyl group, and particularly preferably a hydrogen atom or a methyl group, from the viewpoints that the raw materials are readily available, and that the purification is easier. In addition, the plural R¹s, R²s, and R³s in the formula are particularly preferably the same, from the viewpoints of ease of purification and the like.

Moreover, R¹⁰ in the general formula (1) is a group represented by the general formula (101). Further, n in the general formula (1) represents an integer of 0 to 12. If the value of n exceeds the upper limit, the purification becomes difficult. In addition, an upper limit value of the numeric value range of n in the general formula (1) is more preferably 5, and particularly preferably 3, from the viewpoint that the purification becomes easier. In addition, a lower limit value of the numeric value range of n in the general formula (1) is more preferably 1, and particularly preferably 2, from the viewpoint of the stability of the raw material compound used for forming the repeating unit represented by the general formula (1), in other words, from the viewpoint of producing the polyimide more easily. Accordingly, n in the general formula (1) is particularly preferably an integer of 2 or 3.

Moreover, in the repeating unit (B), R¹, R², R³, and n in the general formula (2) have the same meanings as those of R¹, R², R³, and n in the general formula (1). In other words, R¹, R², R³, and n in the general formula (2) are the same as R¹, R², R³, and n in the general formula (1) (preferred examples thereof are also the same as those of R¹, R², R³, and n in the general formula (1)).

Moreover, the group which can be selected as R¹¹ in the general formula (2) is one selected from groups represented by the general formulae (201) to (203). As R¹¹, the group represented by the general formula (201) is preferable from the viewpoints of heat resistance, transparency, and linear expansion coefficient; the group represented by the general formula (202) is preferable from the viewpoints of heat resistance, transparency, tensile strength, and linear expansion coefficient; and the group represented by the general formula (203) is preferable from the viewpoints of heat resistance, transparency, tensile strength, and break elongation. Note that, in the polyimide according to the present invention, one kind of the repeating unit (B) may be utilized alone, or a combination of multiple kinds of the repeating unit (B) having different kinds of R¹¹s, or the like, may be incorporated.

Further, in the polyimide according to the present invention, the content ratio of the repeating unit (A) to the total amount of the repeating unit (A) represented by the general formula (1) and the repeating unit (B) represented by the general formula (2) is 10 to 70% by mole. If the content of the repeating unit (A) represented by the general formula (1) is less than the lower limit, it is difficult to sufficiently lower the linear expansion coefficient. Meanwhile, if the content exceeds the upper limit, it is difficult to have a tensile strength and/or an elongation characteristic (elongation until breakage) in a better-balanced manner, and a higher toughness cannot be exhibited.

Furthermore, in the polyimide according to the present invention, the content ratio of the repeating unit (A) to the total amount of the repeating unit (A) represented by the general formula (1) and the repeating unit (B) represented by the general formula (2) is more preferably 20 to 60% by mole, further preferably 25 to 55% by mole, and particularly preferably 30 to 50% by mole, from the viewpoint of having a sufficiently high toughness and a sufficiently low linear expansion coefficient in a better-balanced manner.

In addition, the polyimide according to the present invention may contain other repeating units, as long as the effects of the present invention are not impaired. The other repeating units are not particularly limited, and known repeating units capable of constituting the polyimide can be utilized as appropriate. As the other repeating units, for example, repeating units of polyimides described in International Publication Nos. WO2011/099518 and WO2014/034760 may be selected and utilized as appropriate.

Further, the polyimide according to the present invention preferably contains the repeating units (A) and (B) such that the total amount of the repeating unit (A) represented by the general formula (1) and the repeating unit (B) represented by the general formula (2) is 30% by mole or more (more preferably 50% by mole or more, further preferably 70% by mole or more, particularly preferably 98 to 100% by mole) relative to all the repeating units. If the content ratio of the total amount of the repeating units (A) and (B) is less than the lower limit, it tends to be difficult to exhibit the heat resistance, transparency, tensile strength, tensile elongation, and linear expansion coefficient in a well-balanced manner which is not necessarily sufficient. Note that, from the viewpoint of forming the polyimide more efficiently, and from the viewpoint of exhibiting the heat resistance, transparency, tensile strength, tensile elongation, and linear expansion coefficient in a better-balanced manner, it can be stated that the polyimide according to the present invention preferably contains substantially the repeating units (A) and (B) (contains substantially no other repeating units; the total amount of the repeating unit (A) and the repeating unit (B) is more preferably 95% by mole or more, further preferably 98% by mole or more, particularly preferably 99% by mole or more).

In addition, the polyimide film has a linear expansion coefficient of 55 ppm/K or less. If the linear expansion coefficient exceeds the upper limit, the polyimide film tends to be easily peeled off because of thermal history when a composite material is formed by combining the polyimide film with a metal or an inorganic material having a linear expansion coefficient in a range from 5 to 20 ppm/K. Meanwhile, from the viewpoint of more sufficiently suppressing the peeling off of the polyimide film because of the thermal history, and further from the viewpoint that the dimensional stability can be further improved, the polyimide film has a linear expansion coefficient of more preferably −20 to 55 ppm/K, and further preferably 0 to 30 ppm/K. Note that if the linear expansion coefficient is less than the lower limit, the peeling off and curling tend to occur. In addition, as the value of the linear expansion coefficient of the polyimide film, the following value is employed. Specifically, first, a polyimide film to be measured is formed to have a size of a length: 76 mm, a width: 52 mm, and a thickness: 13 μm, and the film is made of the same material as the material (polyimide) for forming the polyimide film. Then, the film is dried in vacuum (at 120° C. for 1 hour), and heated under a nitrogen atmosphere at 200° C. for 1 hour to obtain a dry film. Subsequently, using the dry film thus obtained as a sample, the change in length in the longitudinal direction of the sample at 50° C. to 200° C. is measured by utilizing a thermomechanical analyzer (manufactured by Rigaku Corporation under the trade name of “TMA8310”) as a measuring apparatus and by employing conditions of a tensile mode (49 mN) and a rate of temperature rise of 5° C./minute under a nitrogen atmosphere. Thereafter, the average value of the change in length per 1° C. (1 K) over the temperature range from 50° C. to 200° C. is determined. After that, the average value thus determined is employed as the value of the linear expansion coefficient of the polyimide film of the present invention (the value of the linear expansion coefficient of the polyimide film having a thickness of 13 μm is employed as the value of the linear expansion coefficient of the polyimide film of the present invention).

In addition, the polyimide film of the present invention needs to have a tensile strength of 125 MPa or more. If the tensile strength is less than the lower limit, a film having a higher toughness cannot be obtained. Moreover, from the similar viewpoint, the tensile strength of the polyimide film is more preferably 130 MPa or more, and further preferably 135 MPa or more. Note that an upper limit value of the tensile strength of the polyimide film is not particularly limited, but is preferably 1000 MPa or less. If the value of the tensile strength exceeds the upper limit value, processing tends to be difficult.

In addition, the polyimide film of the present invention needs to have a break elongation of 15% or more. If the break elongation is less than the lower limit, a film having a higher toughness cannot be obtained. Moreover, from the similar viewpoint, the break elongation of the polyimide film is more preferably 20% or more, and further preferably 25% or more. Note that an upper limit value of the break elongation of the polyimide film is not particularly limited, but is preferably 300% or less. If the value of the break elongation exceeds the upper limit value, processing tends to be difficult.

Additionally, as the values of the tensile strength and the break elongation of the polyimide film of the present invention, values determined as follows can be employed. In such measurements, first, “Super Dumbbell cutter (trade name, model: SDMK-1000-D, according to the A22 standard of JIS K7139 (published in 2009))” manufactured by Dumbbell Co., Ltd. is attached to an SD type lever-controlled sample cutter (a cutter manufactured by Dumbbell Co., Ltd. (model: SDL-200)), and the polyimide film (thickness: 13 μm) is cut to prepare a measurement sample. Note that the measurement sample thus obtained has a dumbbell shape (test piece) which basically follows the standard of Type A22 (reduced test piece) described in JIS K7139 (published in 2009), except that the thickness is 13 μm. The size of the measurement sample used is the overall length: 75 mm, the distance between tab portions: 57 mm, the length of the parallel portion: 30 mm, the radius of the shoulders: ≥30 mm, the width of the ends: 10 mm, the width of the central parallel portion: 5 mm, and the thickness: 13 μm; when used, the width between grippers: 57 mm, and the width of the grip sections: 10 mm (the same width as the overall width of the ends). Then, using a Tensilon universal testing machine (for example, model “UCT-10T” manufactured by A&D Company, Limited), the measurement sample is placed such that the width between the grippers is 57 mm, and that the width of the grip sections is 10 mm (the overall width of the ends of the test piece). Subsequently, a tensile test is conducted in which the measurement sample is stretched under conditions of a full scale load: 0.05 kN and a testing speed: 300 mm/minute. Thus, the values of the tensile strength (stress at break [unit: MPa]) and the break elongation (unit: %) are determined (this test is in accordance with JIS K7162 (published in 1994)). Note that the value (%) of the break elongation can be determined by calculating the following equation:

[Break elongation (%)]={(L−L₀)/L₀}×100,

where L₀ is a distance between tab portions of a sample before the tensile test is started (=the width between grippers: 57 mm), and L is a distance between the tab portions of the sample until the breakage in the tensile test (the width between the grippers at break: 57 mm+α).

In addition, the polyimide has an imidization ratio of preferably 90% or more, more preferably 95% or more, and particularly preferably 96 to 100%. If the imidization ratio is less than the lower limit, the heat resistance is lowered, or problems tend to occur such as voids and swelling in the film during heating in some cases. Note that the imidization ratio can be calculated as follows. Specifically, a polyimide to be measured is dissolved into a deuterated solvent such as deuterated chloroform (preferably deuterated chloroform), and subjected to ¹H-NMR measurement. The integrated values of H in N—H at around 10 ppm (10 ppm±1 ppm) and H in COOH at around 12 ppm (12 ppm±1 ppm) are determined from the ¹H-NMR graph so that the imidization ratio can be calculated. In this case, a value calculated as follows is employed as an integration ratio (imidization ratio). Specifically, first, samples are prepared in which acid dianhydride and diamine, which are the raw material compounds, are dissolved into a deuterated solvent (such as DMSO-d₆) capable of dissolving the raw material compounds. Then, ¹H-NMR spectra of these samples are measured. In these ¹H-NMR graphs, the position (chemical shift) and the integrated value of H in the acid dianhydride and the position (chemical shift) and the integrated value of H in the diamine are determined. By using the position and the integrated value of H in the acid dianhydride and the position and the integrated value of H in the diamine as standards, the integration ratio (imidization ratio) is calculated by a relative comparison with respect to the integrated values of H in N—H at around 10 ppm and H in COOH at around 12 ppm in the ¹H-NMR graphs of the polyimide measured. Note that, in the measurement of the imidization ratio, the amount of the polyimide measured for the ¹H-NMR spectra is 0.01 to 5.0 mass % relative to the deuterated solvent (preferably deuterated chloroform), and the amount of each of the acid dianhydride and the diamine, which are the raw material compounds, utilized is 0.01 to 5.0 mass % relative to the deuterated solvent (such as DMSO-d₆) capable of dissolving the raw material compounds. In addition, in the measurement of the imidization ratio, the measurement is conducted with the amount of the polyimide and the amounts of the acid dianhydride and the diamine, which are the raw material compounds, (the above-described concentrations) being adjusted to the same concentration. Additionally, for the 1H-NMR measurement, an NMR measuring apparatus (manufactured by VARIAN under the trade name: UNITY INOVA-600) is employed as a measuring apparatus.

Further, the polyimide has a 5% weight loss temperature (Td5%) of preferably 400° C. or more, and more preferably 450 to 550° C. If the 5% weight loss temperature is less than the lower limit, it tends to be difficult to achieve a sufficient heat resistance. Meanwhile, if the 5% weight loss temperature exceeds the upper limit, it tends to be difficult to produce a polyimide having such a characteristic. Note that the 5% weight loss temperature can be determined by measuring a temperature at which the weight loss of a sample used reaches 5% by heating the sample under conditions of: a nitrogen gas atmosphere with a nitrogen gas flow, a scan temperature set from 30° C. to 550° C., and a rate of temperature rise of: 10° C./min. Additionally, for example, a thermogravimetric analyzer (“TG/DTA220” manufactured by SII NanoTechnology Inc.) can be utilized as a measuring apparatus for the measurement.

Moreover, the polyimide has a glass transition temperature (Tg) of preferably 250° C. or more, and more preferably 300 to 500° C. If the glass transition temperature (Tg) is less than the lower limit, it tends to be difficult to achieve a sufficient heat resistance. Meanwhile, if the glass transition temperature (Tg) exceeds the upper limit, it tends to be difficult to produce a polyimide having such a characteristic. Note that the glass transition temperature (Tg) can be measured simultaneously by the same method for the softening temperature measurement using a thermomechanical analyzer (manufactured by Rigaku Corporation under the trade name of “TMA8311”) as a measuring apparatus. Note that, in the measurement of such a glass transition temperature, the measurement is preferably conducted by scanning a range between 30° C. and 550° C. under a condition of a rate of temperature rise of: 5° C./minute under a nitrogen atmosphere.

Furthermore, the polyimide has a softening temperature of preferably 250 to 550° C., more preferably 350 to 550° C., and further preferably 360 to 510° C. If the softening temperature is less than the lower limit, the heat resistance is lowered, so that when the polyimide film is used as, for example, a substrate for a transparent electrode of a solar cell, a liquid crystal display device, or an organic EL display device, it tends to be difficult to sufficiently suppress quality deterioration (crack formation and the like) of the film (substrate) in a heating step during production of the product. Meanwhile, if the softening temperature exceeds the upper limit, the film thus formed tends to be rather brittle, because the solid-state polymerization reaction does not proceed sufficiently simultaneously with the thermal ring-closure condensation reaction of the polyamic acid in the production of the polyimide.

Note that the softening temperature of the polyimide can be measured as follows. Specifically, as a measurement sample, a film made of a polyimide having a size of 5 mm in length, 5 mm in width, and 0.013 mm (13 μm) in thickness is prepared. Then, using a thermomechanical analyzer (manufactured by Rigaku Corporation under the trade name of “TMA8311”) as a measuring apparatus, the softening temperature can be measured simultaneously with the glass transition temperature (Tg) by penetrating the film using a transparent quartz pin (tip end diameter: 0.5 mm) at a pressure of 500 mN under a condition of a temperature range from 30° C. to 550° C. and employing conditions of a nitrogen atmosphere and a rate of temperature rise of 5° C./minute (the softening temperature can be measured by what is called a penetration method). Note that, in such a measurement, the softening temperature is calculated based on the measurement data according to the method described in JIS K 7196 (1991).

In addition, the polyimide for forming the film has a thermal decomposition temperature (Td) of preferably 450° C. or more, and more preferably 480 to 600° C. If the thermal decomposition temperature (Td) is less than the lower limit, it tends to be difficult to achieve a sufficient heat resistance. Meanwhile, if the thermal decomposition temperature (Td) exceeds the upper limit, it tends to be difficult to produce a polyimide having such a characteristic. Note that the thermal decomposition temperature (Td) can be determined by measuring a temperature at an intersection of tangent lines drawn to decomposition curves before and after thermal decomposition using a TG/DTA220 thermogravimetric analyzer (manufactured by SII NanoTechnology Inc.) under a nitrogen atmosphere under a condition of a rate of temperature rise of 10° C./min.

Further, the polyimide has a number average molecular weight (Mn) of preferably 1000 to 1000000, and more preferably 10000 to 500000, in terms of polystyrene. If the number average molecular weight is less than the lower limit, it tends to be difficult to not only achieve a sufficient heat resistance but also efficiently obtain the polyimide because the polyimide does not sufficiently precipitate from a polymerization solvent during the production. Meanwhile, if the number average molecular weight exceeds the upper limit, the viscosity is increased, and it takes a long time for the dissolution or a large amount of a solvent is required, so that processing tends to be difficult.

In addition, the polyimide for forming the film has a weight average molecular weight (Mw) of preferably 1000 to 5000000 in terms of polystyrene. In addition, a lower limit value of the numeric value range of the weight average molecular weight (Mw) is more preferably 5000, further preferably 10000, and particularly preferably 20000. In addition; an upper limit value of the numeric value range of the weight average molecular weight (Mw) is more preferably 5000000, further preferably 500000, and particularly preferably 100000. If the weight average molecular weight is less than the lower limit, it tends to be difficult to not only achieve a sufficient heat resistance but also efficiently obtain the polyimide because the polyimide does not sufficiently precipitate from a polymerization solvent during the production. Meanwhile, if the weight average molecular weight exceeds the upper limit, the viscosity is increased, and it takes a long time for the dissolution or a large amount of a solvent is required, so that processing tends to be difficult.

Further, the polyimide has a molecular weight distribution (Mw/Mn) of preferably 1.1 to 5.0, and more preferably 1.5 to 3.0. If the molecular weight distribution is less than the lower limit, the production tends to be difficult. Meanwhile, if the molecular weight distribution exceeds the upper limit, it tends to be difficult to obtain a uniform film. Note that the molecular weight (Mw or Mn) and the molecular weight distribution (Mw/Mn) of the polyimide can be determined by converting, into polystyrene, data measured using a measuring apparatus of a gel permeation chromatography (GPC) measuring apparatus (degasser: DG-2080-54 manufactured by JASCO Corporation, liquid transfer pump: PU-2080 manufactured by JASCO Corporation, interface: LC-NetII/ADC manufactured by JASCO Corporation, column: GPC column KF-806M (×two) manufactured by Shodex, column oven: 860-CO manufactured by JASCO Corporation, RI detector: RI-2031 manufactured by JASCO Corporation at a column temperature of 40° C. with a chloroform solvent (flow rate: 1 mL/min.).

Meanwhile, the polyimide in the film is preferably soluble in a casting solvent having a low boiling point. A film made of such a polyimide can be prepared more easily. Note that the casting solvent herein is preferably a solvent having a boiling point of 200° C. or less (more preferably 20 to 150° C., further preferably 30 to 120° C., particularly preferably 40 to 100° C., the most preferably 60° C. to 100° C.) from the viewpoints of solubility, volatility, vapor diffusivity, removability, film formability, productivity, industrial availability, recyclability, the presence or absence of existing facility, and price. Moreover, the solvent having a boiling point of 200° C. or less is more preferably halogen-containing solvents having boiling points of 200° C. or less; further preferably dichloromethane (methylene chloride), trichloromethane (chloroform), carbon tetrachloride, dichloroethane, trichloroethylene, tetrachloroethylene, tetrachloroethane, chlorobenzene, and o-dichlorobenzene; and particularly preferably dichloromethane (methylene chloride) and trichloromethane (chloroform). Note that one of the casting solvents may be utilized alone, or two or more thereof may be utilized in combination.

In addition, the polyimide film preferably has a sufficiently high transparency, and has a total luminous transmittance of more preferably 80% or more (further preferably 85% or more, particularly preferably 87% or more). The polyimide film more preferably has a haze (turbidity) of 5 or less (further preferably 4 or less, particularly preferably 3 or less) from the viewpoint of obtaining a higher transparency. Further, such a polyimide film more preferably has a yellowness index (YI) of 10 or less (further preferably 8 or less, particularly preferably 6 or less) from the viewpoint of obtaining a higher transparency. These total luminous transmittance, haze (turbidity), and yellowness index (YI) can be easily achieved by selecting the kind of the polyimide, and the like, as appropriate. Note that values of these total luminous transmittance, haze (turbidity), and yellowness index (YI) employed are measured by forming a polyimide film having a size of a length: 76 mm, a width: 52 mm, and a thickness: 13 μm as a measurement sample, and using a measuring apparatus manufactured by Nippon Denshoku Industries Co., Ltd under the trade name of “Haze Meter NDH-5000.”

The form of the polyimide film is not particularly limited, as long as it is a film. The polyimide film can be designed as appropriate to have various shapes (circular disc shape, cylindrical shape (a film processed into a tube), or the like).

Further, the thickness of the polyimide film of the present invention is not particularly limited, but is preferably 1 to 500 μm, and more preferably 10 to 200 μm. If the thickness is less than the lower limit, the strength tends to decrease, making the film difficult to handle. Meanwhile, if the thickness exceeds the upper limit, it may be necessary to perform the application multiple times, or the processing tends to be complicated.

In addition, the polyimide film of the present invention is preferably a film having a thickness-direction retardation (Rth) of −1000 to 1000 nm (more preferably −500 to 500 nm, further preferably −250 to 250 nm), which is measured at a wavelength of 590 nm and with respect to the thickness of 10 μm, because effects of suppressing a decrease in contrast and improving the angle of view are obtained when the film is used in a display device. Note that the “thickness-direction retardation (Rth)” of the polyimide film of the present invention can be determined using a measuring apparatus manufactured by AXOMETRICS, Inc. under the trade name of “AxoScan” by: measuring a value of a refractive index (589 nm) of the polyimide film as described later; inputting the measured value into the measuring apparatus; then, measuring the thickness-direction retardation of the polyimide film by using light at a wavelength of 590 nm under conditions of a temperature: 25° C. and a humidity: 40%; and converting the measured value of the thickness-direction retardation thus determined (the value is measured according to the automatic measurement (automatic calculation) of the measuring apparatus) into a retardation value per 10 μm of the thickness of the film. Note that the size of the polyimide film as the measurement sample is not particularly limited, as long as it is larger than a light measurement unit (diameter: approximately 1 cm) of a stage of the measuring apparatus. Nevertheless, the size is preferably a length: 76 mm, a width: 52 mm, and a thickness: 13 μm.

Note that the value of the “refractive index (589 nm) of the polyimide film” utilized in the measurement of the thickness-direction retardation (Rth) can be determined by: forming an unstretched film made of the same kind of polyimide as the polyimide for forming the film to be measured for the retardation; and then, measuring the unstretched film as a measurement sample (note that in the case where the film to be measured is an unstretched film, the film can be directly used as the measurement sample) for the refractive index for light at 589 nm in an in-plane direction (the direction perpendicular to the thickness direction) of the measurement sample by using a refractive index-measuring apparatus (manufactured by Atago Co., Ltd. under the trade name of “NAR-1T SOLID”) as a measuring apparatus under a light source of 589 nm and a temperature condition of 23° C. Note that since the measurement sample is unstretched, the refractive index in the in-plane direction of the film is the same in any direction in the plane, and measuring this refractive index makes it possible to measure the intrinsic refractive index of the polyimide (note that since the measurement sample is unstretched, Nx=Ny is satisfied, where Nx is a refractive index in a direction of a slow axis in the plane, and Ny is a refractive index in an in-plane direction perpendicular to the direction of the slow axis). Accordingly, an unstretched film is utilized to measure the intrinsic refractive index (589 nm) of the polyimide, and the measurement value thus obtained is utilized in the measurement of the above-described thickness-direction retardation (Rth). Here, the size of the polyimide film as a measurement sample is not particularly limited, as long as the size can be utilized in the refractive index-measuring apparatus. The size may be 1 cm square (1 cm in length and width) and 13 μm in thickness.

The polyimide film of the present invention has the values of a sufficiently high tensile strength and a sufficiently high break elongation in a better-balanced manner (has a higher toughness based on these). Thus, the polyimide film of the present invention has not only a higher mechanical strength but also a sufficiently low linear expansion coefficient. This makes it possible to sufficiently suppress the peeling off and the like of the film due to heat even when the film is stacked on a metal substrate or the like. Accordingly, the polyimide film of the present invention is useful in various applications: for example, films for flexible wiring boards, heat-resistant insulating tapes, enameled wires, protective coating agents for semiconductors, liquid crystal orientation films, transparent electro-conductive films for organic ELs, display substrate materials (display substrates such as TFT substrates and transparent electrode substrates (for example, transparent electro-conductive films for organic ELs, and the like)), films for organic EL lighting devices, flexible substrate films, substrate films for flexible organic ELs, flexible transparent electro-conductive films, transparent electro-conductive films for organic thin film-type solar cells, transparent electro-conductive films for dye-sensitized-type solar cells, flexible gas barrier films, substrate materials for touch panels (such as films for touch panels), front films for flexible displays, back films for flexible displays, and the like. Further, as described above, the polyimide film of the present invention has a higher toughness and a higher mechanical strength; in addition, the linear expansion coefficient is sufficiently low. Accordingly, the use of the polyimide film of the present invention in the applications as described above (in particular, applications to display substrate materials (display substrates such as TFT substrates and transparent electrode substrates), substrate materials for touch panels (such as films for touch panels), and the like) makes it possible to sufficiently improve the yields of final products (for example, organic EL elements and the like) because of the mechanical strength and so forth.

A method for producing the polyimide film of the present invention is not particularly limited. For example, it is possible to employ methods for producing a polyimide film, by adopting known methods (for example, methods for producing a polyimide described in WO 2011/099518 A and WO 2014/034760 A) as appropriate, using and reacting

a tetracarboxylic dianhydride represented by the following general formula (3):

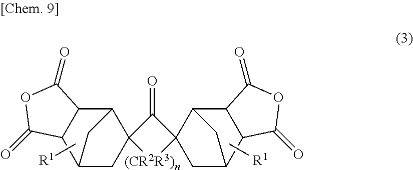

[in the formula (3), R¹, R², R³, and n have the same meanings as those of R¹, R², R³, and n in the general formula (1)], and

an aromatic diamine containing:
a diamine compound (A) represented by the following general formula (301):

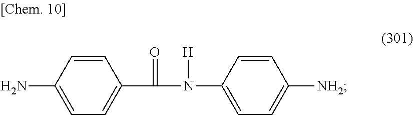

and
at least one diamine compound (B) of compounds represented by the following general formulae (401) to (403):

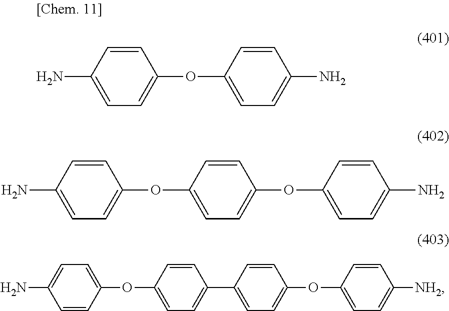

wherein a content ratio of the diamine compound (A) to a total amount of the diamine compounds (A) and (B) is 10 to 70% by mole. Note that a repeating unit derived and formed by the reaction between the tetracarboxylic dianhydride and the diamine compound (A) is the repeating unit (A), and a repeating unit derived and formed by the reaction between the tetracarboxylic dianhydride and the diamine compound (B) is the repeating unit (B).

In addition, as the method for producing the polyimide film of the present invention, it is possible to preferably utilize, for example, a method comprising:

reacting the tetracarboxylic dianhydride represented by the general formula (3) with the aromatic diamine in the presence of a polymerization solvent, to thereby form a polyamic acid containing
a repeating unit (A′) represented by the following general formula (4):

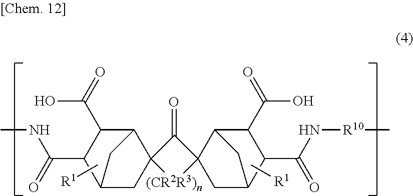

[in the formula (4), R¹, R², R³, and n have the same meanings as those of R¹, R², R³, and n in the general formula (1) (preferred examples thereof also have the same meanings as those of R¹, R², R³, and n in the general formula (1)), and R¹⁰ has the same meaning as that of R¹⁰ in the general formula (1)], and
a repeating unit (B′) represented by the following general formula (5):

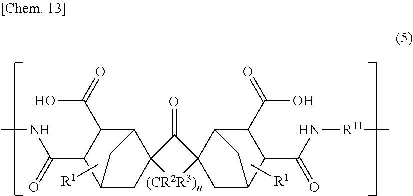

[in the formula (5), R¹, R², R³, and n have the same meanings as those of R¹, R², R³, and n in the general formula (2) (preferred examples thereof also have the same meanings as those of R¹, R², R³, and n in the general formula (2)), and R¹¹ has the same meaning as that of R¹ in the general formula (2) (a preferred example thereof also has the same meaning as that of R¹¹ in the general formula (2))], wherein a content ratio of the repeating unit (A′) to a total amount of the repeating units (A′) and (B′) is 10 to 70% by mole (more preferably 20 to 60% by mole, further preferably 25 to 55% by mole, particularly preferably 30 to 50% by mole);

then, applying a polyamic acid solution containing the polyamic acid onto a surface of a substrate material (for example, a glass substrate material or the like); and

subsequently, subjecting the polyamic acid to imidization, to thereby form a film made of a polyimide (polyimide film) containing the repeating unit (A) represented by the general formula (1) and the repeating unit (B) represented by the general formula (2) while stacked on the substrate material, wherein the content ratio of the repeating unit (A) to the total amount of the repeating units (A) and (B) is 10 to 70% by mole (hereinafter, simply referred to as “method (A)” in some cases).

Regarding the tetracarboxylic dianhydride represented by the general formula (3), R¹, R², and R³ in the formula (3) are each independently one selected from the group consisting of a hydrogen atom, alkyl groups having 1 to 10 carbon atoms, and a fluorine atom, and n is an integer of 0 to 12. R¹, R², R³, and n in the general formula (3) are the same as R¹, R², R³, and n in the general formula (1), and preferred examples thereof are also the same as the preferred examples of R¹, R², R³, and n in the general formula (1). The method for producing the tetracarboxylic dianhydride represented by the general formula (3) is not particularly limited, and known methods can be employed as appropriate. For example, the method described in International Publication No. WO2011/099517, the method described in International Publication No. WO 2011/099518 A, or the like may be employed.

Moreover, from the viewpoints of adjusting the film property, thermal property, mechanical property, optical property, and electrical property, the tetracarboxylic dianhydride represented by the general formula (3) preferably contains at least one of: a compound (I) represented by the following general formula (6):

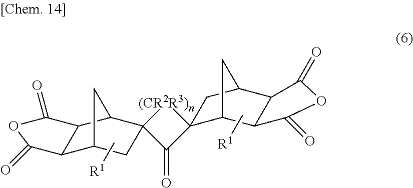

[in the formula (6), R¹, R², R³, and n have the same meanings as those of R¹, R², R³, and n in the general formula (3)]; and a compound (II) represented by the following general formula (7):

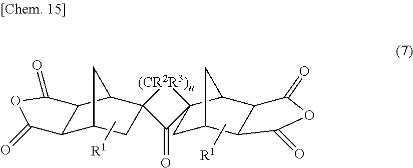

[in the formula (7), R¹, R², R³, and n have the same meanings as those of R¹, R², R³, and n in the general formula (3)], wherein a total amount of the compounds (I) and (II) is 90% by mole or more. The compound (I) represented by the general formula (6) is an isomer of the tetracarboxylic dianhydride represented by the general formula (3) in which the conformation of the two norbornane groups is trans and the configuration of the carbonyl group of the cycloalkanone is endo with respect to each of the two norbornane groups. Meanwhile, the compound (II) represented by the general formula (7) is an isomer of the tetracarboxylic dianhydride represented by the general formula (3) in which the conformation of the two norbornane groups is cis and the configuration of the carbonyl group of the cycloalkanone is endo with respect to each of the two norbornane groups. Note that the method for producing the tetracarboxylic dianhydride containing the isomer(s) at the above-described ratio is not particularly limited, either, and known methods can be employed as appropriate. For example, the method described in WO 2014/034760 A or the like may be employed as appropriate.

Note that commercially available products may be used as the diamine compound represented by the general formula (301) (4,4′-diaminobenzanilide: DABAN), the diamine compound represented by the general formula (401) (4,4′-diaminodiphenyl ether: 4,4′-DDE), the diamine compound represented by the general formula (402) (1,4-bis(4-aminophenoxy)benzene: 4,4-BAB), and the diamine compound represented by the general formula (303) (4,4′-bis(4-aminophenoxy)biphenyl: APBP).

In addition, the aromatic diamine needs to contain the diamine compound (A) represented by the general formula (301) and the at least one diamine compound (B) of compounds represented by the following general formulae (401) to (403) such that the content ratio of the diamine compound (A) to the total amount of the diamine compounds (A) and (B) is 10 to 70% by mole (more preferably 20 to 60% by mole, further preferably 25 to 55% by mole, particularly preferably 30 to 50% by mole). If the content ratio of the diamine compound (A) is outside the range, the content ratio of the repeating unit (A) in the obtained polyimide cannot be 10 to 70% by mole relative to the total amount of the repeating units (A) and (B). This is because the repeating unit derived and formed by the reaction between the tetracarboxylic dianhydride represented by the general formula (3) and the diamine compound (A) is the repeating unit (A) in the polyimide, and because the repeating unit derived and formed by the reaction between the tetracarboxylic dianhydride represented by the general formula (3) and the diamine compound (B) is the repeating unit (B) in the polyimide.

In addition, the polymerization solvent used in the method (A) is preferably an organic solvent capable of dissolving both the tetracarboxylic dianhydride represented by the general formula (3) and the aromatic diamine. Examples of the organic solvent include aprotic polar solvents such as N-methyl-2-pyrrolidone, N,N-dimethylacetamide, N,N-dimethylformamide, dimethyl sulfoxide, γ-butyrolactone, propylene carbonate, tetramethylurea, 1,3-dimethyl-2-imidazolidinone, hexamethylphosphoric triamide, and pyridine; phenol-based solvents such as m-cresol, xylenol, phenol, and halogenated phenols; ether-based solvents such as tetrahydrofuran, dioxane, Cellosolve, glyme, and diglyme; aromatic solvents such as benzene, toluene, and xylene; ketone-based solvents such as cyclopentanone and cyclohexanone; nitrile-based solvents such as acetonitrile and benzonitrile; and the like. One of the polymerization solvents (organic solvents) may be used alone, or two or more thereof may be used in mixture.

In addition, the ratio between the tetracarboxylic dianhydride represented by the general formula (3) and the aromatic diamine used in the method (A) is such that the acid anhydride groups of the tetracarboxylic dianhydride represented by the general formula (3) is preferably 0.2 to 2 equivalents, and more preferably 0.8 to 1.2 equivalents, relative to 1 equivalent of the amino groups of the aromatic diamine. If the ratio of the use is less than the lower limit, there is a tendency that the polymerization reaction proceeds inefficiently, so that a polyamic acid having a high molecular weight cannot be obtained. Meanwhile, if the ratio of the use exceeds the upper limit, there is a tendency that a polyamic acid having a high molecular weight cannot be obtained as in the above-described case.

Further, the amount of the polymerization solvent (organic solvent) used in the method (A) is preferably such that a total amount of the tetracarboxylic dianhydride represented by the general formula (3) and the aromatic diamine is 0.1 to 50% by mass (more preferably 10 to 30% by mass) relative to the total amount of the reaction solution. If the amount of the organic solvent used is less than the lower limit, there is a tendency that the polyamic acid cannot be obtained efficiently. Meanwhile, if the amount of the organic solvent used exceeds the upper limit, stirring tends to be difficult because of the increased viscosity.

In addition, in the method (A), the method for reacting the tetracarboxylic dianhydride represented by the general formula (3) with the aromatic diamine is not particularly limited, and a known method capable of conducting the reaction between the tetracarboxylic dianhydride and the aromatic diamine can be employed as appropriate. For example, a method may be employed in which the aromatic diamine is dissolved in a solvent under an inert atmosphere of nitrogen, helium, argon, or the like under atmospheric pressure; then, the tetracarboxylic dianhydride represented by the general formula (3) is added thereto; and then the reaction is allowed to proceed for 10 to 48 hours. In addition, in this reaction, the temperature condition is preferably about −20 to 100° C. If the reaction time or the reaction temperature is less than the lower limit, it tends to be difficult to conduct the reaction sufficiently. Meanwhile, if the reaction time or the reaction temperature exceeds the upper limit, there is a tendency that the possibility of inclusion of a substance (oxygen or the like) which degrades the polymerization product is increased, so that the molecular weight is lowered.

Moreover, regarding the repeating unit (A′) in the polyamic acid formed as an intermediate in the method (A), R¹, R², R³, and n in the general formula (4) have the same meanings as those of R¹, R², R³, and n in the general formula (1), and preferred examples thereof are also the same as those of R¹, R², R³, and n in the general formula (1). In addition, R¹⁰ in the general formula (4) has the same meaning as that of R¹⁰ in the general formula (1), and a preferred example thereof is also the same as that of R¹⁰ in the general formula (1). Meanwhile, regarding the repeating unit (B′) in the polyamic acid, R¹, R², R³, and n in the general formula (5) have the same meanings as those of R¹, R², R³, and n in the general formula (2), and preferred examples thereof are also the same as those of R¹, R², R³, and n in the general formula (2). In addition, R¹¹ in the general formula (5) has the same meaning as that of R¹¹ in the general formula (2), and a preferred example thereof is also the same as that of R¹¹ in the general formula (2).

Further, the polyamic acid formed as the intermediate in the method (A) has an intrinsic viscosity [η] of preferably 0.05 to 3.0 dL/g, and more preferably 0.1 to 2.0 dL/g. If the intrinsic viscosity [η] is less than 0.05 dL/g, when a film-shaped polyimide is produced by using the polyamic acid, the resultant film tends to be brittle. Meanwhile, if the intrinsic viscosity [η] exceeds 3.0 dL/g, the processability deteriorates because of the excessively high viscosity, so that it becomes difficult to obtain a uniform film when the film is produced from the polyamic acid, for example.

In addition, the intrinsic viscosity [η] of the polyamic acid can be measured as follows. Specifically, first, by using N,N-dimethylacetamide as a solvent, a measurement sample (solution) is obtained in which the polyamic acid is dissolved in the N,N-dimethylacetamide at a concentration of 0.5 g/dL. Next, by using the measurement sample, the viscosity of the measurement sample is measured with a kinematic viscometer under a temperature condition of 30° C., and the thus determined value is employed as the intrinsic viscosity [η]. Note that an automatic viscometer (trade name: “VMC-252”) manufactured by RIGO CO., LTD. is used as the kinematic viscometer.

Meanwhile, the substrate material used in the method (A) is not particularly limited, and a substrate material (for example, a glass plate or a metal plate) made of a known material usable for film formation can be used as appropriate according to the shape of the desired film made of a polyimide and the like.

Further, in the method (A), the method for applying the solution of the polyamic acid onto the substrate material is not particularly limited. A known method such as a spin coating method, a spray coating method, a dip coating method, a dropping method, a gravure printing method, a screen printing method, a relief printing method, a die coating method, a curtain coating method, or an inkjet method can be employed as appropriate, for example.

In the method (A), the method for the imidization of the polyamic acid is not particularly limited, either, as long as the polyamic acid can be subjected to imidization. Known methods (such as imidization methods described in WO 2011/099518 A and WO 2014/034760 A) can be employed as appropriate without particular limitation. As the method for the imidization of the polyamic acid, it is preferable to employ, for example, a method in which the polyamic acid containing the repeating unit represented by the general formula (4) is subjected to imidization by performing a heat treatment thereon under a temperature condition of 60 to 400° C. (more preferably 60 to 370° C., further preferably 150 to 360° C.), or a method in which the imidization is conducted by using what is called an “imidization agent.”

Alternatively, in the method (A), the following imidization method may be employed. Specifically, the reaction liquid (the reaction liquid containing the polyamic acid) obtained by reacting the tetracarboxylic dianhydride represented by the general formula (3) with the aromatic diamine in the polymerization solvent (organic solvent) is used as it is without isolating the polyamic acid before the imidization of the polyamic acid. The reaction liquid is applied onto the substrate material, and then subjected to a drying treatment to thereby remove the solvent and subsequently subjected to the heat treatment for the imidization. In the process of the drying treatment, the temperature condition is preferably 0 to 180° C., and more preferably 60 to 150° C. Note that the polyamic acid may be isolated from the reaction liquid and utilized. In this case, the method for isolating the polyamic acid is not particularly limited. A known method capable of isolating the polyamic acid can be employed as appropriate. For example, a method in which the polyamic acid is isolated as a product of reprecipitation may be employed.

The method (A) makes it possible to obtain the above-described polyimide film of the present invention comprising a polyimide containing the repeating unit (A) represented by the general formula (1) and the repeating unit (B) represented by the general formula (2) while stacked on a substrate material, wherein the content ratio of the repeating unit (A) to the total amount of the repeating units (A) and (B) is 10 to 70% by mole. Note that when the thus obtained polyimide film is peeled and recovered from the substrate material, the peeling method is not particularly limited, and known methods can be employed as appropriate. For example, a method in which a laminate comprising the polyimide film stacked on the substrate material is immersed in high-temperature water (for example, water of 80° C. or more), so that the polyimide film is peeled from the substrate material, or the like may be employed.

[Organic Electroluminescent Element]

An organic electroluminescent element of the present invention comprises the above-described polyimide film of the present invention.

The structure of the organic electroluminescent element is not particularly limited, and a known structure can be utilized as appropriate, except that, for example, the organic electroluminescent element comprises the polyimide film of the present invention. Additionally, the organic electroluminescent element is not particularly limited, and, for example, is preferably one comprising the above-described polyimide film of the present invention as a substrate for stacking a transparent electrode from the viewpoint of improving the production yield.

Hereinafter, one embodiment preferably usable as the organic electroluminescent element (organic EL element) of the present invention will be described briefly with reference to the drawing. Note that, in the following description and drawing, the same or equivalent elements are denoted by the same reference numerals, and overlapping descriptions will be omitted.

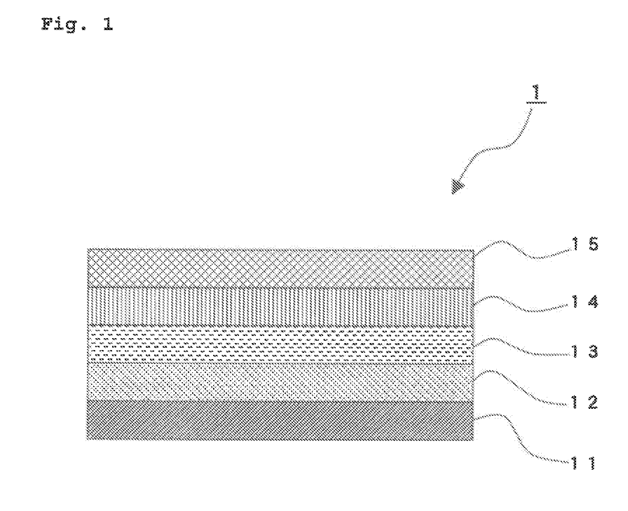

FIG. 1 is a schematic longitudinal sectional view of a preferred embodiment of the organic electroluminescent element (organic EL element) of the present invention. An organic EL element 1 of the embodiment shown in FIG. 1 comprises a polyimide film 11, a gas barrier layer 12, a transparent electrode layer 13, an organic layer 14, and a metal electrode layer 15.

In the organic EL element, the polyimide film 11 comprises the above-described polyimide film of the present invention. The polyimide film 11 in the present embodiment is used as a substrate of an organic EL element (substrate for stacking a transparent electrode).

Moreover, the gas barrier layer 12 is a layer preferably utilized to suppress the permeability of a gas (including water vapor) into the element, the layer having a higher gas-permeation prevention performance. The gas barrier layer 12 is not particularly limited. For example, it is possible to preferably utilize: a layer made of an inorganic material such as SiN, SiO₂, SiC, SiOₓN_{y}, TiO₂, or Al₂O₃; an ultrathin plate glass; or the like. The gas barrier layer 12 may be stacked such that a known gas barrier layer is disposed (formed) on the polyimide film 11 as appropriate.

In addition, the thickness of the gas barrier layer 12 is not particularly limited, and is preferably in a range from 0.01 to 5000 μm, and more preferably in a range from 0.1 to 100 μm. If the thickness is less than the lower limit, there is a tendency that a sufficient gas barrier performance cannot be obtained. Meanwhile, if the thickness exceeds the upper limit, such a thick layer tends to eliminate such characteristics as flexibility and softness.

The transparent electrode layer 13 is a layer utilized as a transparent electrode of the organic EL element. The material of the transparent electrode layer 13 is not particularly limited, as long as it is utilizable for the transparent electrode of the organic EL element. For example, indium oxide, zinc oxide, tin oxide, and indium tin oxide (ITO) which is a composite material thereof, gold, platinum, silver, or copper is used. Of these materials, ITO is preferable, for example, from the viewpoint of the balance between the transparency and the electroconductivity.

In addition, the thickness of the transparent electrode layer 13 is preferably in a range from 20 to 500 nm. If the thickness is less than the lower limit, the electroconductivity tends to be insufficient. Meanwhile, if the thickness exceeds the upper limit, the transparency tends to be so insufficient that emitted EL light cannot be extracted to the outside sufficiently.

Note that, between the gas barrier layer 12 and the transparent electrode layer 13, what is called a thin film transistor (TFT) layer may be formed. Providing such a TFT layer makes it also possible to form a device (TFT element) having the transparent electrode connected to the TFT. The material (such as oxide semiconductor, amorphous silicon, polysilicon, organic transistor) and the structure of the TFT layer are not particularly limited, and can be designed as appropriate based on known TFT structures. Moreover, in the case where the TFT layer is provided on a laminate of the polyimide film 11 and the gas barrier layer 12, the laminate of these can also be utilized as what is called a TFT substrate. Note that the method for producing the TFT layer is not particularly limited, and known methods can be employed as appropriate. For example, production methods such as a low-temperature polysilicon method, a high-temperature polysilicon method, an amorphous silicon method, and an oxide semiconductor method may be employed.

The organic layer 14 should be usable for forming the organic EL element, and the structure is not particularly limited. Organic layers utilizable for known organic EL elements can be utilized as appropriate. Moreover, the structure of the organic layer 14 is not particularly limited, either, and known structures can be employed as appropriate. For example, the organic layer may be a laminate including a hole transporting layer, a light emitting layer, and an electron transporting layer.

As the material of the hole transporting layer, known materials capable of forming hole transporting layers can be used as appropriate. For example, it is possible to use derivatives of naphthyldiamine (α-NPD), triphenylamine, triphenyldiamine derivatives (TPD), benzidine, pyrazoline, styrylamine, hydrazone, triphenylmethane, carbazole, and the like, and other similar compounds.

In addition, the light emitting layer is a layer where light is emitted by recombination of electrons and holes injected from the electrode layer and so forth. The material of the light emitting layer is not particularly limited, and known materials capable of forming light emitting layers of organic EL elements can be used as appropriate. For example, it is possible to utilize as appropriate known materials which emit light by voltage application: materials obtained by doping 4,4′-N,N′-dicarbazole-biphenyl (CBP) with tris(phenylpyridinato)iridium(III) complex (Ir(ppy)₃); materials made of fluorescent organic solids such as 8-hydroxyquinoline aluminum (Alq₃, green, low molecular weight), bis-(8-hydroxy)quinaldine aluminum phenoxide (Alq′₂OPh, blue, low molecular weight), 5,10,15,20-tetraphenyl-21H,23H-porphine (TPP, red, low molecular weight), poly(9,9-dioctylfluorene-2,7-diyl) (PFO, blue, high molecular weight), poly[2-methoxy-5-(2′-ethylhexyloxy)-1,4-(1-cyanovinylene)phenylene] (MEH-CN-PPV, red, high molecular weight), and anthracene; and the like.

Further, the material of the electron transporting layer is not particularly limited, and known materials capable of forming electron transporting layers can be used as appropriate. For example, it is possible to use aluminum quinolinol complex (Alq), phenanthroline derivatives, oxadiazole derivatives, triazole derivatives, phenylquinoxaline derivatives, and silole derivatives.

Furthermore, in the case where the organic layer 14 is a laminate including a hole transporting layer, a light emitting layer, and an electron transporting layer, the thickness of each layer of the hole transporting layer, the light emitting layer, and the electron transporting layer is not particularly limited. Nevertheless, the thickness is preferably in a range from 1 to 50 nm (hole transporting layer), in a range from 5 to 200 nm (light emitting layer), and in a range from 5 to 200 nm (electron transporting layer). In addition, the entire thickness of the organic layer 14 is preferably in a range from 20 to 600 nm.

The metal electrode layer 15 is an electrode made of a metal. The material of the metal electrode is not 16 particularly limited, and a substance having a small work function can be used as appropriate. Examples thereof include aluminum, MgAg, MgIn, and AlLi. In addition, the thickness of the metal electrode layer 15 is preferably in a range from 50 to 500 nm. If the thickness is less than the lower limit, the electroconductivity tends to decrease. Meanwhile, if the thickness exceeds the upper limit, there is a tendency that peeling easily occurs or cracks are easily formed.

Note that the method for producing the organic EL element is not particularly limited. For example, a method may be employed in which the above-described polyimide film of the present invention is prepared; then, the gas barrier layer, the transparent electrode, the organic layer, and the metal electrode are sequentially stacked on the surface of the polyimide film for the production.

The method for stacking the gas barrier layer 12 on the surface of the polyimide film 11 is not particularly limited, and known methods such as a vapor deposition method and a sputtering method can be employed as appropriate. In particular, a sputtering method is preferably employed from the viewpoint of forming a dense film. Moreover, as the method for stacking the transparent electrode layer 13 on the surface of the gas barrier layer 12, known methods such as a vapor deposition method and a sputtering method can be employed as appropriate. In particular, a sputtering method is preferably employed from the viewpoint of forming a dense film.

In addition, the method for stacking the organic layer 14 on the surface of the transparent electrode layer 13 is not particularly limited, either. For example, in the case where the organic layer is a laminate including a hole transporting layer, a light emitting layer, and an electron transporting layer as described above, these layers should be sequentially stacked on the transparent electrode layer 13. Note that the method for stacking each layer in the organic layer 14 is not particularly limited, and known methods can be utilized as appropriate. For example, a vapor deposition method, a sputtering method, an application method, and the like can be employed. Among these methods, a vapor deposition method is preferably employed from the viewpoint of sufficiently preventing decomposition, deterioration, and denaturation of the organic layer.

Further, the method for stacking the metal electrode layer 15 on the organic layer 14 is not particularly limited, and known methods can be utilized as appropriate. For example, a vapor deposition method, a sputtering method, and the like can be employed. Among these methods, a vapor deposition method is preferably employed from the viewpoint of sufficiently preventing decomposition, deterioration, and denaturation of the already-formed organic layer 14.

In addition, producing the organic EL element as described above makes it possible to form an organic EL element comprising the polyimide film 11 utilized as a substrate supporting what is called an element section. Thus, the yield can be improved because of the mechanical strength, and the flexibility can also be sufficiently increased.

Hereinabove, a preferred embodiment of the organic EL element of the present invention has been described. However, the organic EL element of the present invention is not limited to the above-described embodiment. For example, in the above-described embodiment, the organic layer 14 is a laminate of a hole transporting layer, a light emitting layer, and an electron transporting layer. Nevertheless, the form of the organic layer is not particularly limited, and known structures of organic layers can be employed as appropriate. For example, the organic layer may comprise a laminate of a hole injection layer and a light emitting layer; the organic layer may comprise a laminate of a light emitting layer and an electron injection layer; the organic layer may comprise a laminate of a hole injection layer, a light emitting layer, and an electron injection layer; the organic layer may comprise a laminate of a buffer layer, and a hole transporting layer, and an electron transporting layer; or the like are also possible. Note that the material of each layer in such other forms of the organic layer is not particularly limited, and known materials can be used as appropriate. For example, a perylene derivative or the like may be used as the material of the electron injection layer. A triphenylamine derivative or the like may be used as the material of the hole injection layer. Copper phthalocyanine, PEDOT, or the like may be used as the material of an anode buffer layer. Additionally, layers which are not provided in the above-described embodiment may be provided as appropriate, as long as the layers can be utilized in the organic EL element. For example, from the viewpoint of facilitating charge injection or hole injection into the organic layer 14, a layer made of a metal fluoride such as lithium fluoride (LiF) or Li₂O₃, a highly active alkaline earth metal such as Ca, Ba, or Cs, an organic insulating material, or the like may be provided on the transparent electrode layer 13 or the organic layer 14.

[Transparent Electro-Conductive Laminate]

A transparent electro-conductive laminate of the present invention comprises:

the above-described polyimide film of the present invention; and

a thin film made of an electro-conductive material and stacked on the polyimide film.

Accordingly, the transparent electro-conductive laminate of the present invention comprises the thin film made of an electro-conductive material stacked on the polyimide film of the present invention. The transparent electro-conductive laminate has a total luminous transmittance of preferably 78% or more (more preferably 80% or more, further preferably 82% or more) from the viewpoint of being transparent. The total luminous transmittance can be easily achieved by selecting as appropriate the kind of the polyimide film according to the present invention, the kind of the electro-conductive material, and the like. Note that a value measured using a measuring apparatus manufactured by Nippon Denshoku Industries Co., Ltd. under the trade name of “Haze Meter NDH-5000” can be employed as the total luminous transmittance.

In addition, the electro-conductive material is not particularly limited, as long as the material has electroconductivity. Known electro-conductive materials which can be used for transparent electrodes of solar cells, organic EL elements, liquid crystal display devices, or the like, can be utilized as appropriate. Examples thereof include metals such as gold, silver, chromium, copper, and tungsten; composite materials of metal oxides of tin, indium, zinc, cadmium, titanium, and the like doped with other elements (for example, tin, tellurium, cadmium, molybdenum, tungsten, fluorine, zinc, germanium, aluminum, and the like) (for example, Indium Tin Oxide (ITO (In₂O₃:Sn)), Fluorine doped Tin Oxide (FTO (SnO₂:F)), Aluminum doped Zinc Oxide (AZO (ZnO:Al)), Indium doped Zinc Oxide (IZO (ZnO:I)), Germanium doped Zinc Oxide (GZO (ZnO:Ge)), and the like); and the like. In addition, of these electro-conductive materials, ITO (particularly preferably, ITO containing 3 to 15% by mass of tin) is preferably used, because the transparency and the electroconductivity can be exhibited at higher levels in a well-balanced manner.

The film thickness design of the thin film made of the electro-conductive material (electro-conductive thin film) can be changed as appropriate depending on the application and the like, and the film thickness is not particularly limited. The film thickness is preferably 1 to 2000 nm, more preferably 10 nm to 1000 nm, further preferably 20 to 500 nm, and particularly preferably 20 to 200 nm. If the thickness of the electro-conductive thin film is less than the lower limit, there is a tendency that the surface resistance value is not sufficiently lowered, so that the photoelectric conversion efficiency decreases in a case of use for a solar cell or the like. Meanwhile, if the thickness exceeds the upper limit, the transmittance tends to decrease, and the production efficiency tends to decrease because of long film formation time.

The method for stacking the thin film made of the electro-conductive material on the above-described polyimide film of the present invention is not particularly limited, and a known method can be utilized as appropriate. For example, it is possible to employ a method in which the thin film is stacked on the polyimide film by forming a thin film of the electro-conductive material on the polyimide film by a vapor deposition method such as a sputtering method, a vacuum vapor deposition method, an ion plating method, or a plasma CVD method. Note that, when the thin film is stacked on the polyimide film, a gas barrier film may be formed on the polyimide film in advance, and the thin film may be stacked on the polyimide film with the gas barrier film interposed therebetween. In addition, the gas barrier film is not particularly limited, and a known film which can be utilized for a transparent electrode of a solar cell, an organic EL element, or a liquid crystal display device, or the like can be utilized as appropriate. As the method for forming the gas barrier film, a known method can also be utilized as appropriate.

The transparent electro-conductive laminate of the present invention is particularly useful, for example, as a transparent electrode of a solar cell, a transparent electrode of a display device (such as an organic EL display device, a liquid crystal display device), or the like, because the polyimide film has a higher toughness. Hence, the yields of these final products can be improved more sufficiently.

[Touch Panel, Solar Cell, Display Device]

A touch panel, a solar cell, and a display device of the present invention each comprise the above-described transparent electro-conductive laminate of the present invention.

Herein, the “display device” is not particularly limited, as long as the transparent electro-conductive laminate can be utilized therein. Examples of the display device include liquid crystal display devices and organic EL display devices. In addition, the structure of each of the touch panel, the solar cell, and the display device is not particularly limited, except that the structure comprises the transparent electro-conductive laminate of the present invention. A known structure can be employed as appropriate depending on the desired specifications. The structure is, for example, as follows. Specifically, the structure of the touch panel may include a transparent electrode and another transparent electrode arranged with a space provided therebetween. The structure of the solar cell may include a transparent electrode, a semiconductor layer, and an electro-conductive layer as a counter electrode. The structure of the organic EL display device may include a transparent electrode, an organic layer, and an electro-conductive layer as a counter electrode. The structure of the liquid crystal display device may include a transparent electrode, a liquid crystal layer, and an electro-conductive layer as a counter electrode. In addition, the material of each of the layers such as the organic layer, the liquid crystal layer, and the semiconductor layer is not particularly limited, and a known material can be utilized as appropriate. In addition, in each of the touch panel, the solar cell, and the display device of the present invention, the transparent electro-conductive laminate of the present invention is preferably utilized as the transparent electrode. The utilization of the transparent electro-conductive laminate of the present invention as the transparent electrode as described above makes it possible to produce touch panels, solar cells, and display devices at high yields with sufficiently high qualities, because formation of fractures and the like in the transparent electrode layer (the thin film made of the electro-conductive material) is sufficiently suppressed, even when the transparent electro-conductive laminate is exposed to high temperature conditions ordinarily employed in the production of touch panels, solar cells, and display devices (liquid crystal display devices and organic EL display devices).

### EXAMPLES

Hereinafter, the present invention will be described more specifically based on Examples and Comparative Examples. However, the present invention is not limited to Examples below.

First, the chemical formulae of aromatic diamines used in Examples and Comparative Examples are shown below together with abbreviations of these compounds.

[Chem. 16]

| Abbreviation | Chemical formula |
|---|---|
| 4,4-BAB | 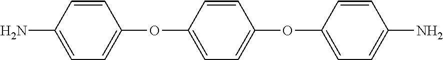 [SMILES: Nc1ccc(Oc2ccc(Oc3ccc(N)cc3)cc2)cc1] |
| APBP | 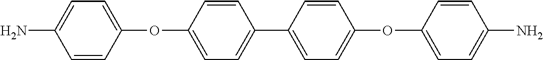 [SMILES: Nc1ccc(Oc2ccc(-c3ccc(Oc4ccc(N)cc4)cc3)cc2)cc1] |
| DABAN | 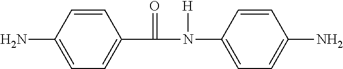 [SMILES: Nc1ccc(NC(=O)c2ccc(N)cc2)cc1] |
| 6FDA | 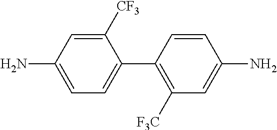 [SMILES: Nc1ccc(-c2ccc(N)cc2C(F)(F)F)c(C(F)(F)F)c1] |
| TPE-R | 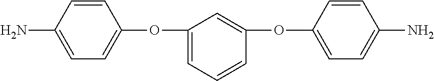 [SMILES: Nc1ccc(Oc2cccc(Oc3ccc(N)cc3)c2)cc1] |
| BAPP | 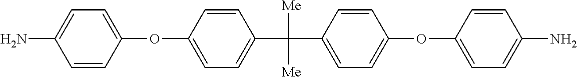 [SMILES: CC(C)(c1ccc(Oc2ccc(N)cc2)cc1)c1ccc(Oc2ccc(N)cc2)cc1] |
| BAPS | 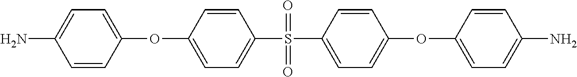 [SMILES: Nc1ccc(Oc2ccc(S(=O)(=O)c3ccc(Oc4ccc(N)cc4)cc3)cc2)cc1] |
| 4,4′-DDE | 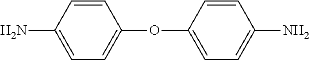 [SMILES: Nc1ccc(Oc2ccc(N)cc2)cc1] |
| BAPS-M | 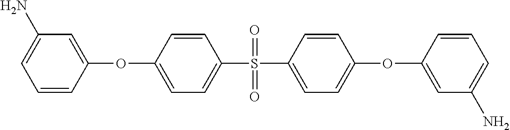 [SMILES: Nc1cccc(Oc2ccc(S(=O)(=O)c3ccc(Oc4cccc(N)c4)cc3)cc2)c1] |
| Bis-AF | 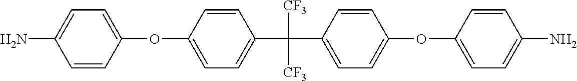 [SMILES: Nc1ccc(Oc2ccc(C(c3ccc(Oc4ccc(N)cc4)cc3)(C(F)(F)F)C(F)(F)F)cc2)cc1] |
| 3,3-BAB | 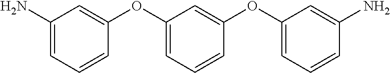 [SMILES: Nc1cccc(Oc2cccc(Oc3cccc(N)c3)c2)c1] |
| m-Tol | 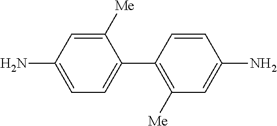 [SMILES: Cc1cc(N)ccc1-c1ccc(N)cc1C] |

Note that all of the aromatic diamines utilized were commercially available products (4,4-BAB: manufactured by Wakayama Seika Kogyo Co., Ltd., APBP: manufactured by Nipponjunryo Chemicals K. K., DABAN: manufactured by Nipponjunryo Chemicals K. K., 6FDA: manufactured by Tokyo Chemical Industry Co., Ltd., TPE-R: manufactured by Wakayama Seika Kogyo Co., Ltd., BAPP: manufactured by Wakayama Seika Kogyo Co., Ltd., BAPS: manufactured by Wakayama Seika Kogyo Co., Ltd., 4, 4′-DDE: manufactured by Tokyo Chemical Industry Co., Ltd., BAPS-M: manufactured by Wakayama Seika Kogyo Co., Ltd., Bis-AF: manufactured by Tokyo Chemical Industry Co., Ltd., 3, 3-BAB: manufactured by Mitsui Fine Chemicals, Inc., m-Tol: manufactured by Wakayama Seika Kogyo Co., Ltd.).

Next, methods for evaluating characteristics of polyimide films and the like obtained in Examples and Comparative Examples are described.

<Identification of Molecular Structures>

The molecular structures of the compounds obtained in Examples and Comparative Examples were identified by measuring IR with an IR measuring apparatus (manufactured by JASCO Corporation under the trade name: FT/IR-4100).

<Measurement of Intrinsic Viscosity [η]>

The value (unit: dL/g) of the intrinsic viscosity [η] of each polyamic acid obtained as an intermediate in Examples and Comparative Examples was measured, as described above, with an automatic viscometer (trade name: “VMC-252”) manufactured by RIGO CO., LTD. under a temperature condition of 30° C., and using a measurement sample in N,N-dimethylacetamide as a solvent at a concentration of 0.5 g/dL.

<Measurement of Tensile Strength and Break Elongation>

The tensile strength (unit: MPa) and the break elongation (unit: %) of each polyimide film (thickness: 13 μm) in Examples and Comparative Examples were measured as follows. Specifically, first, “Super Dumbbell cutter (trade name, model: SDMK-1000-D, according to the A22 standard of JIS K7139 (published in 2009))” manufactured by Dumbbell Co., Ltd. was attached to an SD type lever-controlled sample cutter (a cutter manufactured by Dumbbell Co., Ltd. (model: SDL-200)), and the polyimide film was cut to a size of the overall length: 75 mm, the distance between tab portions: 57 mm, the length of the parallel portion: 30 mm, the radius of the shoulders: 30 mm, the width of the ends: 10 mm, the width of the central parallel portion: 5 mm, and the thickness: 13 μm. Thereby, a dumbbell-shaped test piece was prepared as a measurement sample (which followed the standard of Type A22 (reduced test piece) of JIS K7139, except that the thickness was 13 μm). Then, using a Tensilon universal testing machine (for example, model “UCT-10T” manufactured by A&D Company, Limited), the measurement sample was placed such that the width between the grippers was 57 mm, and that the width of the grip sections was 10 mm (the overall width of the ends). Subsequently, a tensile test was conducted in which the measurement sample was stretched under conditions of a full scale load: 0.05 kN and a testing speed: 300 mm/minute. Thus, the values of the tensile strength and the break elongation were determined. Note that this test was in accordance with JIS K7162 (published in 1994). In addition, the value (%) of the break elongation was determined by calculating the following equation:

[Break elongation (%)]={(L−L₀)/L₀}×100,

where L₀ is a distance between tab portions of a sample before the tensile test is started (=the width between grippers: 57 mm), and L is a distance between the tab portions of the sample until the breakage in the tensile test (the width between the grippers at break: 57 mm+α).

<Measurement of Glass Transition Temperature (Tg)>

The value (unit: ° C.) of the glass transition temperature (Tg) of each compound (compound for forming a film) obtained in Examples and Comparative Examples was measured using each polyimide film produced in Examples and Comparative Examples, with a thermomechanical analyzer (manufactured by Rigaku Corporation under the trade name of “TMA8311”) as a measuring apparatus, and by employing the same method (the same conditions) as the following method for measuring a softening temperature, simultaneously with the softening temperature measurement.

<Measurement of Softening Temperature>

The value (unit: ° C.) of the softening temperature (softening point) of each compound (compound for forming a film) obtained in Examples and Comparative Examples was measured using each polyimide film produced in Examples and Comparative Examples, with a thermomechanical analyzer (manufactured by Rigaku Corporation under the trade name of “TMA8311” as a measuring apparatus, and by penetrating the film using a transparent quartz pin (tip end diameter: 0.5 mm) at a pressure of 500 mN under conditions of a nitrogen atmosphere, a rate of temperature rise of 5° C./minute, and a temperature range from 30° C. to 550° C. (scan temperature) (measurement by what is called a penetration method). In this measurement, the softening temperature was calculated based on the measurement data according to the method described in JIS K7196 (1991), except that the measurement sample was utilized.

<Measurement of 5% Weight Loss Temperature (Td5%)>

The value (unit: ° C.) of the 5% weight loss temperature (Td5%) of each compound obtained in Examples and so forth was determined using each polyimide film produced in Examples and Comparative Examples, with a thermogravimetric analyzer (“TG/DTA220” manufactured by SII NanoTechnology Inc.), and by measuring a temperature at which the weight loss of a sample used reached 5% by heating the sample under conditions of: 10° C./min, a scan temperature set from 30° C. to 550° C., and a nitrogen atmosphere with a nitrogen gas flow.

<Measurement of Total Luminous Transmittance, Haze (Turbidity), and Yellowness Index (YI)>

The value (unit: %) of the total luminous transmittance, the haze (turbidity), and the yellowness index (YI) were determined by the measurements according to JIS K7361-1 (published in 1997) using each polyimide film produced in Examples and Comparative Examples, with a measuring apparatus manufactured by Nippon Denshoku Industries Co., Ltd. under the trade name of “Haze Meter NDH-5000.”

<Measurement of Refractive Index>

The refractive index (refractive index for light at 589 nm) of each polyimide film produced in Examples and Comparative Examples was determined by: producing a polyimide film (unstretched film) by the same method employed in Examples and Comparative Examples; cutting the film into a size of 1 cm square (1 cm in length and width) and 13 μm in thickness for use as a measurement sample; and measuring the refractive index (intrinsic refractive index of the polyimide) for light at 589 nm in an in-plane direction (the direction perpendicular to the thickness direction), with a refractive index-measuring apparatus (manufactured by Atago Co., Ltd. under the trade name of “NAR-1T SOLID”) as a measuring apparatus under a light source of 589 nm and a temperature condition of 23° C.

<Thickness-Direction Retardation (Rth)>

The value (unit: nm) of the thickness-direction retardation (Rth) was determined using each polyimide film (length: 76 mm, width: 52 mm, thickness: 13 μm) produced in Examples and Comparative Examples directly as a measurement sample, with a measuring apparatus manufactured by AXOMETRICS, Inc. under the trade name of “AxoScan,” and by: inputting the value of the refractive index of the polyimide film (the refractive index for light at 589 nm of the film determined by the above-described refractive index measurement); then, measuring the thickness-direction retardation by using light at a wavelength of 590 nm under conditions of a temperature: 25° C. and a humidity: 40%; and converting the measured value of the thickness-direction retardation thus determined (the value was measured according to the automatic measurement of the measuring apparatus), into a retardation value per 10 μm of the thickness of the film.

### Example 1

<Step of Preparing Tetracarboxylic Dianhydride>

According to the methods described in Synthesis Example 1, Example 1, and Example 2 of WO 2011/099518 A, a tetracarboxylic dianhydride (norbornane-2-spiro-α-cyclopentanone-α′-spiro-2″-norbornane-5,5″,6,6″-tetracarboxylic dianhydride) represented by the following general formula (8) was prepared:

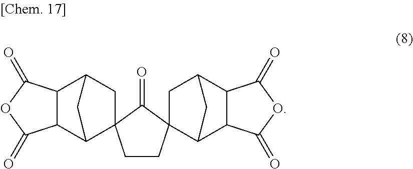

<Step of Preparing Polyamic Acid>

First, a 30-ml three-necked flask was sufficiently dried by heating with a heat gun. Next, the gas atmosphere in the sufficiently dried three-necked flask was replaced with nitrogen to create a nitrogen atmosphere in the three-necked flask. Subsequently, as the aromatic diamine, a mixture of 0.0409 g of 4,4′-diaminobenzanilide (0.18 mol: DABAN) and 0.2105 g of 1,4-bis(4-aminophenoxy)benzene (0.72 mol: 4,4-BAB) was prepared (the mole ratio of 4,4-BAB and DABAN ([DABAN]: [4,4-BAB]) was 20:80). After the aromatic diamine was added into the three-necked flask, 2.7 g of N,N-dimethylacetamide was further added thereinto, and the aromatic diamine (the mixture of 4,4-BAB and DABAN) was dissolved with stirring in the N, N-dimethylacetamide. Thus, a solution was obtained.

Next, 0.3459 g (0.90 mmol) of a compound represented by the general formula (7) was added into the three-necked flask containing the solution under a nitrogen atmosphere, and then stirred under a nitrogen atmosphere at room temperature (25° C.) for 12 hours to obtain a reaction liquid. Thus, a polyamic acid was formed in the reaction liquid.

Note that, by using a portion of the reaction liquid (the N,N-dimethylacetamide solution of the polyamic acid: polyamic acid solution), an N,N-dimethylacetamide solution having a polyamic acid concentration of 0.5 g/dL was prepared, and the intrinsic viscosity [η] of the polyamic acid, which was a reaction intermediate, was measured as described above. As a result, the polyamic acid had an intrinsic viscosity [η] of 0.54 dL/g.

<Step of Preparing Film Made of Polyimide>

A large format glass slide (manufactured by Matsunami Glass Ind., Ltd. under the trade name of “S9213”, length: 76 mm, width: 52 mm, thickness: 1.3 mm) was prepared as a glass substrate. The reaction liquid (polyamic acid solution) obtained as described above was spin-coated onto the surface of the glass substrate, so that the coating film had a thickness of 13 μm after being thermally cured. Thus, a coating film was formed on the glass substrate. After that, the glass substrate on which the coating film was formed was placed on a hot plate of 60° C. and allowed to stand for 2 hours. The solvent was removed from the coating film by evaporation (solvent removal treatment).

After the solvent removal treatment, the glass substrate on which the coating film was formed was introduced into an inert oven with nitrogen flowing at a flow rate of 3 L/minute. The glass substrate was allowed to stand inside the inert oven under a nitrogen atmosphere and a temperature condition of 25° C. for 0.5 hours, then heated under a temperature condition of 135° C. for 0.5 hours, and further heated under a temperature condition of 350° C. (final heating temperature) for 1 hour to cure the coating film. Thereby, a polyimide-coated glass was obtained in which a thin film made of a polyimide (polyimide film) was coated on the glass substrate.

Next, the thus obtained polyimide-coated glass was immersed in 90° C. hot water, so that the polyimide film was peeled from the glass substrate. Thus, the polyimide film (a film having a size of 76 mm in length, 52 mm in width, and 13 μm in thickness) was obtained.

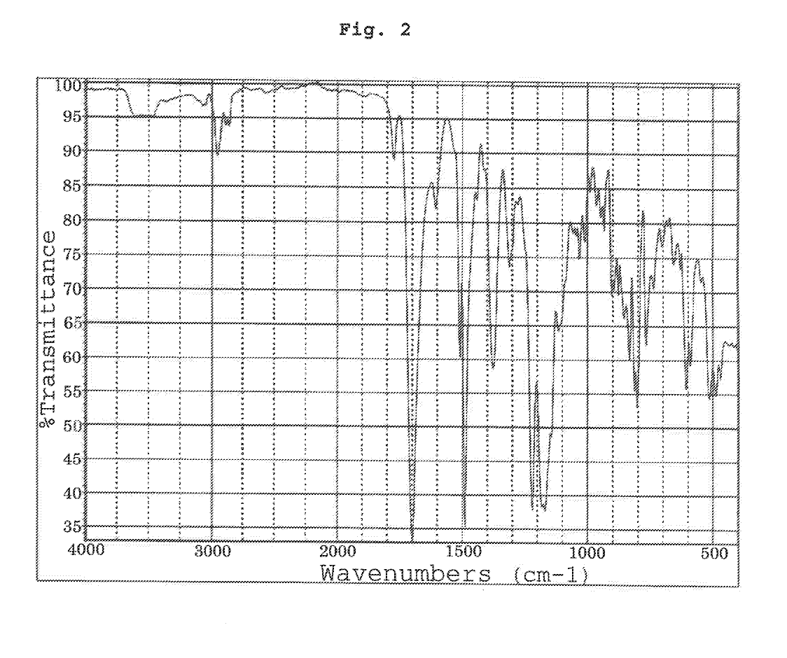

Note that, to identify the molecular structure of the compound for forming the polyimide film thus obtained, the IR spectrum was measured using the IR measuring apparatus (manufactured by JASCO Corporation under the trade name: FT/IR-4100). FIG. 2 shows the IR spectrum obtained as a result of such a measurement. As is apparent from the result shown in FIG. 2, C═O stretching vibration of imidocarbonyl was observed at 1699 cm⁻¹ for the compound constituting the film formed in Example 1. From the molecular structure identified based on this result and so forth, the obtained film was confirmed to be made of a polyimide.

In addition, based on the kind and amount ratio of the monomers used, in the obtained polyimide, the content ratio of the repeating unit (the repeating unit corresponding to the repeating unit (A)) corresponding to the repeating unit represented by the general formula (1) to the repeating unit (the repeating unit corresponding to the repeating unit (B)) corresponding to the repeating unit represented by the general formula (2) was 20:80 in terms of the mole ratio ([the repeating unit corresponding to the repeating unit (A)]: [the repeating unit corresponding to the repeating unit (B)]). Further, Table 1 shows the results of evaluating the characteristics (Tg, softening temperature, and so forth determined by the above-described methods for evaluating characteristics) of the obtained polyimide film.

### Examples 2 to 6

In each Example, a film made of a polyimide was produced in the same manner as in Example 1, except that the kind of the aromatic diamines was changed to ones shown in Table 1. Note that the IR spectrum measurements of the obtained films confirmed that the films obtained in Examples were made of polyimides. In addition, Table 1 shows the results of evaluating the characteristics (the viscosity of the polyamic acid, and the Tg, softening temperature, and so forth of the polyamide film determined by the above-described methods for evaluating characteristics) of each Example.

TABLE 1

| | | Viscosity of | Final | | |
|---|---|---|---|---|---|
| | Aromatic diamine | polyamic | heating | | Softening |
| | (mole ratio is shown in | acid [η] | temperature | Tg | temperature |
| | parentheses) | (dL/g) | (° C.) | (° C.) | (° C.) |
| Example 1 | mixture of DABAN and 4,4-BAB | 0.54 | 350 | 353 | 482 |
| | (DABAN:4,4-BAB = 20:80) | | | | |
| Example 2 | mixture of DABAN and APBP | 0.52 | 350 | 342 | 449 |
| | (DABAN:APBP = 20:80) | | | | |
| Example 3 | mixture of DABAN and APBP | 0.49 | 350 | 343 | 476 |
| | (DABAN:APBP = 40:60) | | | | |
| Example 4 | mixture of DABAN and APBP | 0.55 | 350 | 455 | 470 |
| | (DABAN:APBP = 60:40) | | | | |
| Example 5 | mixture of DABAN and 4,4′-DDE | 0.61 | 350 | 380 | 449 |
| | (DABAN:4,4′-DDE = 20:80) | | | | |
| Example 6 | mixture of DABAN and 4,4′-DDE | 0.58 | 350 | 384 | 468 |
| | (DABAN:4,4′-DDE = 40:60) | | | | |

| | | Total | | | | | | Linear |
|---|---|---|---|---|---|---|---|---|
| | | luminous | | | | Tensile | Break | expansion |
| | Td5 % | transmittance | | | Rth | strength | elongation | coefficient |
| | (° C.) | (%) | HAZE | YI | (nm) | (MPa) | (%) | (ppm/K) |
| Example 1 | 498 | 87 | 1.1 | 3.9 | 220 | 203 | 53 | 52 |
| Example 2 | 499 | 89 | 0.6 | 1.7 | 208 | 188 | 69 | 53 |
| Example 3 | 501 | 88 | 0.2 | 1.4 | 248 | 207 | 27 | 34 |
| Example 4 | 494 | 88 | 0.6 | 1.9 | 720 | 213 | 17 | 21 |
| Example 5 | 492 | 89 | 0.6 | 1.7 | 93 | 180 | 39 | 45 |
| Example 6 | 490 | 89 | 0.3 | 1.5 | 398 | 198 | 27 | 27 |

Note that, based on the kind and so forth of the aromatic diamines used, in the polyamides obtained in Examples 2 to 6, the content ratio of the repeating unit (the repeating unit corresponding to the repeating unit (A)) corresponding to the repeating unit represented by the general formula (1) to the repeating unit (the repeating unit corresponding to the repeating unit (B)) corresponding to the repeating unit represented by the general formula (2) was 20:80 in Example 2, 40:60 in Example 3, 60:40 in Example 4, 20:80 in Example 5, and 40:60 in Example 6 in terms of the mole ratio ([the repeating unit corresponding to the repeating unit (A)]: [the repeating unit corresponding to the repeating unit (B)]).

### Comparative Examples 1 to 11

Films made of polyimides were produced in the same manner as in Example 1, except that the kind of the aromatic diamines was changed to ones shown in Table 2, and further that the temperatures shown in Table 2 were employed as the final heating temperature inside the inert oven in the step of preparing a film made of a polyimide. Note that the IR spectrum measurements of the obtained films confirmed that the films obtained in the examples were made of polyimides. In addition, Table 2 shows the results of evaluating the characteristics (the viscosity of the polyamic acid, and the Tg, softening temperature, and so forth of the polyamide film determined by the above-described methods for evaluating characteristics) of each example.

### Comparative Example 12

A film made of a polyimide was produced in the same manner as in Example 1, except that: the kind of the aromatic diamines was changed to one shown in Table 2; in the step of preparing a polyamic acid, at the time of obtaining a reaction liquid, by changing the temperature condition, stirring under a nitrogen atmosphere for 12 hours at 60° C. is conducted instead of stirring under a nitrogen atmosphere at room temperature (25° C.) for 12 hours; further, the temperature shown in Table 2 was employed as the final heating temperature inside the inert oven in the step of preparing a film made of a polyimide. Note that the IR spectrum measurement of the obtained film confirmed that the film obtained in the example was made of a polyimide. In addition, Table 2 shows the results of evaluating the characteristics (the viscosity of the polyamic acid, and the Tg, softening temperature, and so forth of the polyamide film determined by the above-described methods for evaluating characteristics) of the example.

TABLE 2

| | | Viscosity | Final | | | | Total | | | | | | |
|---|---|---|---|---|---|---|---|---|---|---|---|---|---|
| | Aromatic diamine | of | heating | | Softening | | luminous | | | | | Break | Linear |
| | (mole ratio | polyamic | temper- | | temper- | | transmit- | | | | Tensile | elon- | expansion |
| | is shown in | acid [η] | ature | Tg | ature | Td5 % | tance | | | Rth | strength | gation | coefficient |
| | parentheses) | (dL/g) | (° C.) | (° C.) | (° C.) | (° C.) | (%) | HAZE | YI | (nm) | (MPa) | (%) | (ppm/K) |
| Comparative | 4,4-BAB | 0.98 | 340 | 305 | 475 | 496 | 87 | 3 | 4 | 121 | 186 | 74 | 64 |
| Example 1 | (100% by mole) | | | | | | | | | | | | |
| Comparative | APBP | 0.91 | 320 | 295 | 474 | 499 | 87 | 4.9 | 3.9 | 96 | 133 | 74 | 59 |
| Example 2 | (100% by mole) | | | | | | | | | | | | |
| Comparative | 4,4′-DDE | 1.00 | 300 | 347 | 480 | 496 | 88 | 1.7 | 2.2 | 136 | 85 | 7 | 50 |
| Example 3 | (100% by mole) | | | | | | | | | | | | |
| Comparative | DABAN | 0.91 | 340 | not | 502 | 501 | 88 | 0.7 | 2.4 | 793 | 125 | 4 | 11 |
| Example 4 | (100% by mole) | | | detected | | | | | | | | | |
| Comparative | BAPP | 0.51 | 300 | 294 | 375 | 493 | 89 | 1.4 | 1.5 | 11 | 92 | 60 | 68 |
| Example 5 | (100% by mole) | | | | | | | | | | | | |
| Comparative | BAPS | 0.64 | 300 | 364 | 434 | 466 | 89 | 1.1 | 1.2 | 21 | 92 | 41 | 65 |
| Example 6 | (100% by mole) | | | | | | | | | | | | |
| Comparative | TPE-R | 0.79 | 300 | 288 | 288 | 485 | 90 | 1.1 | 1.4 | 6 | 98 | 129 | 60 |
| Example 7 | (100% by mole) | | | | | | | | | | | | |
| Comparative | BAPS-M | 0.22 | 300 | 327 | 406 | 463 | 90 | 1 | 0.9 | 2.3 | 78 | 9 | 61 |
| Example 8 | (100% by mole) | | | | | | | | | | | | |
| Comparative | Bis-AF | 0.58 | 340 | 276 | 392 | 499 | 89 | 6.9 | 1.9 | 20 | 67 | 8 | 64 |
| Example 9 | (100% by mole) | | | | | | | | | | | | |
| Comparative | 3,3-BAB | 0.31 | 300 | 265 | 265 | 493 | 90 | 1.5 | 0.8 | 3 | 65 | 29 | 65 |
| Example 10 | (100% by mole) | | | | | | | | | | | | |
| Comparative | m-Tol | 1.45 | 350 | not | 465 | 475 | 90 | 1.1 | 1.5 | 237 | 11 | 1 | 41 |
| Example 11 | (100% by mole) | | | detected | | | | | | | | | |
| Comparative | 6FDA | 0.36 | 360 | 331 | 461 | 483 | 90 | 0.8 | 1.3 | 11 | 108 | 6 | 60 |
| Example 12 | (100% by mole) | | | | | | | | | | | | |

Note that, in each of the polyamides obtained in Comparative Examples 1 to 12, since one compound was used as the aromatic diamine, a polyimide containing both the repeating unit corresponding to the repeating unit (A) and the repeating unit corresponding to the repeating unit (B) was not formed.

### Comparative Examples 13 to 34

In each Comparative Examples, a film made of a polyimide was produced in the same manner as in Example 1, except that the kind of the aromatic diamines was changed to ones shown in Tables 3 and 4. Note that the IR spectrum measurements of the obtained films confirmed that the films obtained in the examples were made of polyimides. In addition, Tables 3 and 4 show the results of evaluating the characteristics (the viscosity of the polyamic acid, and the Tg, softening temperature, and so forth of the polyamide film determined by the above-described methods for evaluating characteristics) of each example.

TABLE 3

| | | Viscosity of | Final | | |
|---|---|---|---|---|---|
| | Aromatic diamine | polyamic | heating | | Softening |
| | (mole ratio is shown in | acid [η] | temperature | Tg | temperature |
| | parentheses) | (dL/g) | (° C.) | (° C.) | (° C.) |
| Comparative | mixture of DABAN and 4,4-BAB | 0.60 | 350 | not | 500 |
| Example 13 | (DABAN:4,4-BAB = 80:20) | | | detected | |
| Comparative | mixture of DABAN and APBP | 0.59 | 350 | not | 466 |
| Example 14 | (DABAN:APBP = 80:20) | | | detected | |
| Comparative | mixture of DABAN and 4,4′-DDE | 0.59 | 350 | not | 481 |
| Example 15 | (DABAN:4,4′-DDE = 80:20) | | | detected | |
| Comparative | mixture of DABAN and BAPP | 0.56 | 350 | 328 | 328 |
| Example 16 | (DABAN:BAPP = 20:80) | | | | |
| Comparative | mixture of DABAN and BAPP | 0.58 | 350 | 361 | 453 |
| Example 17 | (DABAN:BAPP = 40:60) | | | | |
| Comparative | mixture of DABAN and BAPP | 0.40 | 350 | 335 | 483 |
| Example 18 | (DABAN:BAPP = 60:40) | | | | |
| Comparative | mixture of DABAN and BAPP | 0.47 | 350 | not | 491 |
| Example 19 | (DABAN:BAPP = 80:20) | | | detected | |
| Comparative | mixture of DABAN and BAPS | 0.42 | 350 | 356 | 444 |
| Example 20 | (DABAN:BAPS = 20:80) | | | | |
| Comparative | mixture of DABAN and BAPS | 0.57 | 350 | 361 | 461 |
| Example 21 | (DABAN:BAPS = 40:60) | | | | |
| Comparative | mixture of DABAN and BAPS | 0.63 | 350 | 369 | 476 |
| Example 22 | (DABAN:BAPS = 60:40) | | | | |

| | | Total | | | | | | Linear |
|---|---|---|---|---|---|---|---|---|
| | | luminous | | | | Tensile | Break | expansion |
| | Td5 % | transmittance | | | Rth | strength | elongation | coefficient |
| | (° C.) | (%) | HAZE | YI | (nm) | (MPa) | (%) | (ppm/K) |
| Comparative | 497 | 86 | 5.9 | 1.3 | 775 | 143 | 6 | 14 |
| Example 13 | | | | | | | | |
| Comparative | 495 | 88 | 0.4 | 1.8 | 932 | 181 | 9 | 16 |
| Example 14 | | | | | | | | |
| Comparative | 497 | 87 | 1.5 | 2.0 | 728 | 161 | 9 | 13 |
| Example 15 | | | | | | | | |
| Comparative | 489 | 89 | 1.1 | 0.2 | 46 | 118 | 80 | 64 |
| Example 16 | | | | | | | | |
| Comparative | 493 | 89 | 1.3 | 0.6 | 97 | 113 | 69 | 55 |
| Example 17 | | | | | | | | |
| Comparative | 489 | 88 | 3.1 | 1.5 | 208 | 122 | 11 | 42 |
| Example 18 | | | | | | | | |
| Comparative | 496 | 87 | 3.6 | 1.5 | 803 | 138 | 7 | 19 |
| Example 19 | | | | | | | | |
| Comparative | 481 | 89 | 1.7 | 0.3 | 53 | 92 | 21 | 55 |
| Example 20 | | | | | | | | |
| Comparative | 484 | 88 | 4.1 | 0.7 | 110 | 86 | 19 | 55 |
| Example 21 | | | | | | | | |
| Comparative | 485 | 87 | 3.9 | 1.4 | 252 | 127 | 10 | 38 |
| Example 22 | | | | | | | | |

TABLE 4

| | | Viscosity of | Final | | |
|---|---|---|---|---|---|
| | Aromatic diamine | polyamic | heating | | Softening |
| | (mole ratio is shown in | acid [η] | temperature | Tg | temperature |
| | parentheses) | (dL/g) | (° C.) | (° C.) | (° C.) |
| Comparative | mixture of DABAN and BAPS-M | 0.45 | 350 | 300 | 300 |
| Example 23 | (DABAN:BAPS-M = 20:80) | | | | |
| Comparative | mixture of DABAN and BAPS-M | 0.45 | 350 | 308 | 452 |
| Example 24 | (DABAN:BAPS-M = 40:60) | | | | |
| Comparative | mixture of DABAN and BAPS-M | 0.44 | 350 | 283 | 469 |
| Example 25 | (DABAN:BAPS-M = 60:40) | | | | |
| Comparative | mixture of DABAN and BAPS-M | 0.60 | 350 | not | 447 |
| Example 26 | (DABAN:BAPS-M = 80:20) | | | detected | |
| Comparative | mixture of DABAN and m-Tol | 1.22 | 350 | 356 | 445 |
| Example 27 | (DABAN:m-Tol = 20:80) | | | | |
| Comparative | mixture of DABAN and m-Tol | 1.13 | 350 | not | 431 |
| Example 28 | (DABAN:m-Tol = 40:60) | | | detected | |
| Comparative | mixture of DABAN and m-Tol | 0.78 | 350 | 372 | 482 |
| Example 29 | (DABAN:m-Tol = 60:40) | | | | |
| Comparative | mixture of DABAN and m-Tol | 0.76 | 350 | 396 | 494 |
| Example 30 | (DABAN:m-Tol = 80:20) | | | | |
| Comparative | mixture of DABAN and TPE-R | 0.44 | 350 | 318 | 416 |
| Example 31 | (DABAN:TPE-R = 20:80) | | | | |
| Comparative | mixture of DABAN and TPE-R | 0.67 | 350 | 332 | 451 |
| Example 32 | (DABAN:TPE-R = 40:60) | | | | |
| Comparative | mixture of DABAN and TPE-R | 0.54 | 350 | 351 | 481 |
| Example 33 | (DABAN:TPE-R = 60:40) | | | | |
| Comparative | mixture of DABAN and TPE-R | 0.59 | 350 | not | 502 |
| Example 34 | (DABAN:TPE-R = 80:20) | | | detected | |

| | | Total | | | | | | Linear |
|---|---|---|---|---|---|---|---|---|
| | | luminous | | | | Tensile | Break | expansion |
| | Td5 % | transmittance | | | Rth | strength | elongation | coefficient |
| | (° C.) | (%) | HAZE | YI | (nm) | (MPa) | (%) | (ppm/K) |
| Comparative | 485 | 89 | 0.9 | 0.4 | 10 | 88 | 31 | 55 |
| Example 23 | | | | | | | | |
| Comparative | 484 | 88 | 2.8 | 1.0 | 6 | 97 | 13 | 62 |
| Example 24 | | | | | | | | |
| Comparative | 483 | 88 | 3.7 | 1.5 | 77 | 99 | 8 | 54 |
| Example 25 | | | | | | | | |
| Comparative | 483 | 87 | 2.2 | 0.8 | 661 | 152 | 7 | 25 |
| Example 26 | | | | | | | | |
| Comparative | 481 | 88 | 4.3 | 2.4 | 659 | 86 | 1 | 22 |
| Example 27 | | | | | | | | |
| Comparative | 484 | 88 | 2.9 | 1.2 | 774 | 121 | 5 | 16 |
| Example 28 | | | | | | | | |
| Comparative | 485 | 87 | 4.7 | 1.5 | 876 | 146 | 7 | 15 |
| Example 29 | | | | | | | | |
| Comparative | 488 | 87 | 5.0 | 1.1 | 900 | 96 | 4 | 11 |
| Example 30 | | | | | | | | |
| Comparative | 491 | 80 | 13.5 | 12.5 | 168 | 95 | 34 | 60 |
| Example 31 | | | | | | | | |
| Comparative | 493 | 85 | 11.4 | 3.7 | 213 | 114 | 14 | 41 |
| Example 32 | | | | | | | | |
| Comparative | 491 | 83 | 10.0 | 5.8 | 726 | 143 | 9 | 23 |
| Example 33 | | | | | | | | |
| Comparative | 499 | 84 | 9.0 | 3.4 | 966 | 156 | 6 | 16 |
| Example 34 | | | | | | | | |

Note that, based on the kind and so forth of the aromatic diamines used, in the polyamides obtained in Comparative Examples 13 to 15, the content ratio of the repeating unit corresponding to the repeating unit (A) to the repeating unit corresponding to the repeating unit (B) was 80:20 in Comparative Example 13, 80:20 in Comparative Example 14, and 80:20 in Comparative Example 15 in terms of the mole ratio ([the repeating unit corresponding to the repeating unit (A)]:[the repeating unit corresponding to the repeating unit (B)]). Meanwhile, based on the kind and so forth of the aromatic diamines used, the polyamides obtained in Comparative Examples 16 to 34 each contained the repeating unit (the repeating unit corresponding to the repeating unit (A)) corresponding to the repeating unit represented by the general formula (1), but the kind of the repeating unit contained in combination therewith was a repeating unit other than the repeating unit corresponding to the repeating unit (B).

[Evaluation of Characteristics of Polyimide Films]

As is apparent from the results shown in Table 1, each of the polyimide films of the present invention (Examples 1 to 6) had a tensile strength of 125 MPa or more and a break elongation of 15% or more. It was found that the polyimide films of the present invention (Examples 1 to 6) had the tensile strength and the elongation characteristic (elongation characteristic until the breakage) at higher levels in a balanced manner, and had a higher toughness. Moreover, each of the polyimide films of the present invention (Examples 1 to 6) had a linear expansion coefficient of 55 ppm/K or less. It was found that the polyimide films of the present invention (Examples 1 to 6) also exhibited sufficiently low values of the linear expansion coefficient. Further, each of the polyimide films of the present invention (Examples 1 to 6) had a Tg of 342° C. or more, a softening temperature of 449° C. or more, and a 5% weight loss temperature of 490° C. or more. These also revealed that the polyimide films of the present invention (Examples 1 to 6) had an extremely high heat resistance. Furthermore, each of the polyimide films of the present invention (Examples 1 to 6) had a total luminous transmittance of 87% or more. It was also found that the polyimide films of the present invention (Examples 1 to 6) had a sufficiently high transparency. From these results, it was found out that the polyimide films obtained in Examples (the polyimide films of the present invention) had a high heat resistance and a sufficient transparency, and had a higher toughness (high toughness) and a sufficiently low linear expansion coefficient at higher levels in a well-balanced manner.

On the other hand, the polyimide films obtained in Comparative Examples 1 and 2 (each made of a polyimide containing the repeating unit corresponding to the repeating unit (B) at a ratio of 100% by mole based on the monomer used and so forth (the repeating unit of the polyimide obtained in Comparative Example 1 was the repeating unit (B) represented by the general formula (2), and R¹¹ in the formula was the group represented by the formula (202); the repeating unit of the polyimide obtained in Comparative Example 2 was the repeating unit (B) represented by the general formula (2), and R¹¹ in the formula was the group represented by the formula (203))) had a tensile strength of 125 MPa or more and a break elongation of 15% or more. However, the values of the linear expansion coefficient were 59 ppm/K or more, and the polyimide films obtained in Comparative Examples 1 and 2 were not necessarily sufficient in terms of having a higher toughness and a lower linear expansion coefficient at higher levels in a well-balanced manner.

In addition, the polyimide film obtained in Comparative Example 3 (made of a polyimide containing the repeating unit corresponding to the repeating unit (B) at a ratio of 100% by mole based on the monomer used and so forth (the repeating unit was represented by the general formula (2), and R¹¹ in the formula was the group represented by the formula (201))) had a tensile strength of 85 MPa and a break elongation of 7%. The polyimide film obtained in Comparative Example 3 did not necessarily have a sufficient toughness (mechanical strength) in comparison with the polyimide films of the present invention (Examples 1 to 6).

Moreover, the polyimide film obtained in Comparative Example 4 (made of a polyimide containing the repeating unit corresponding to the repeating unit (A) at a ratio of 100% by mole based on the monomer used and so forth) had a tensile strength of 125 MPa and a break elongation of 4%. The polyimide film obtained in Comparative Example 4 did not necessarily have a sufficient toughness (mechanical strength) in comparison with the polyimide films of the present invention (Examples 1 to 6).

Further, in the polyimide films obtained in Comparative Examples 5 to 12 each made of a polyimide containing the repeating unit other than the repeating units corresponding to the repeating units (A) and (B), the values of the tensile strength was 108 MPa or less. The polyimide films obtained in Comparative Examples 5 to 12 did not necessarily have a sufficient toughness (mechanical strength) in comparison with the polyimide films of the present invention (Examples 1 to 6).

Furthermore, in the polyimide films obtained in Comparative Examples 13 to 15 (each made of a polyimide containing the repeating unit corresponding to the repeating unit (A) at a content ratio of 80% by mole relative to the total amount of the repeating units respectively corresponding to the repeating units (A) and (B), based on the monomer used and so forth), the values of the break elongation were 9% or less. A sufficient toughness (mechanical strength) was not necessarily obtained in comparison with the polyimide films of the present invention (Examples 1 to 6).

Furthermore, the polyimide films obtained in Comparative Examples 16 to 34 (each made of a polyimide containing the repeating unit corresponding to the repeating unit (A) based on the monomer used and so forth, but the kind of the repeating unit contained in combination therewith was not the repeating unit (B)) had a tensile strength of less than 125 MPa, and/or the values of the break elongation were less than 15%. A sufficient toughness (mechanical strength) was not necessarily obtained in comparison with the polyimide films of the present invention (Examples 1 to 6).

These results revealed that preparing a film made of a polyimide containing the repeating unit (A) and the repeating unit (B) in combination such that the content ratio of the repeating unit (A) to the total amount of the repeating units (A) and (B) was 10 to 70% by mole made it possible to produce a film having a higher toughness and a lower linear expansion coefficient at higher levels in a well-balanced manner.

### INDUSTRIAL APPLICABILITY

As described above, according to the present invention, it is possible to provide a polyimide film and an organic electroluminescent element using the same, the polyimide film being capable of having: a tensile strength and an elongation characteristic at higher levels in a well-balanced manner; a higher toughness based on the tensile strength and break elongation; a sufficiently low linear expansion coefficient; and the sufficiently high toughness and the sufficiently low linear expansion coefficient at higher levels in a well-balanced manner. According to the present invention, it is also possible to provide a transparent electro-conductive laminate using the polyimide film as well as a touch panel, a solar cell, and a display device using the transparent electro-conductive laminate.

In addition, the polyimide film of the present invention has a higher toughness, an excellent mechanical strength, and also a sufficiently low linear expansion coefficient, and is capable of exhibiting these characteristics in a well-balanced manner. Accordingly, when the polyimide film of the present invention is used, for example, as a substrate material for an organic EL display, a liquid-crystal display, a touch panel, or the like, the excellent mechanical strength makes it possible to more sufficiently suppress damage due to stress and so forth generated during practical operations, and the sufficiently low linear expansion coefficient makes it possible to more sufficiently suppress fracture, peeling off, and the like that occur between metal materials due to heat. Hence, the yields of final products can be improved at higher levels. From these viewpoints, the polyimide film of the present invention is particularly useful, for example, as films for flexible wiring boards, heat-resistant insulating tapes, enameled wires, protective coating agents for semiconductors, liquid crystal orientation films, transparent electro-conductive films for organic ELs (organic electroluminescence), films for organic EL lighting devices, flexible substrate films, substrate films for flexible organic ELs, flexible transparent electro-conductive films, transparent electro-conductive films for organic thin film-type solar cells, transparent electro-conductive films for dye-sensitized-type solar cells, flexible gas barrier films, films for touch panels, front films for flexible displays, back films for flexible displays, and the like.

### REFERENCE SIGNS LIST

1: organic EL element
11: polyimide film
12: gas barrier layer
13: transparent electrode layer
14: organic layer
15: metal electrode layer

1. A polyimide film comprising a polyimide containing:
a repeating unit (A) represented by the following general formula (1): 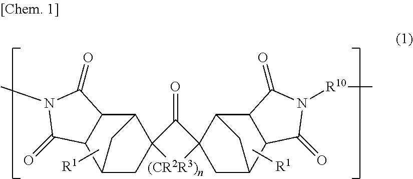
[in the formula (1), R¹, R², and R³ each independently represent one selected from the group consisting of a hydrogen atom, alkyl groups having 1 to 10 carbon atoms, and a fluorine atom, R¹⁰ represents a group represented by the following general formula (101): 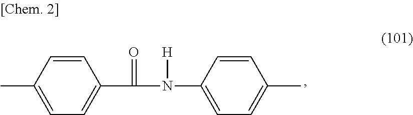
and n represents an integer of 0 to 12]; and
a repeating unit (B) represented by the following general formula (2): 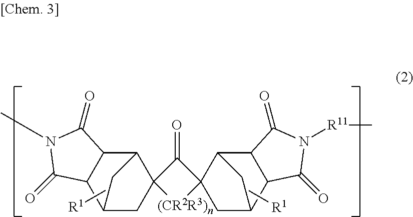
[in the formula (2), R¹, R², and R³ each independently represent one selected from the group consisting of a hydrogen atom, alkyl groups having 1 to 10 carbon atoms, and a fluorine atom, R¹¹ represents one selected from groups represented by the following general formulae (201) to (203): 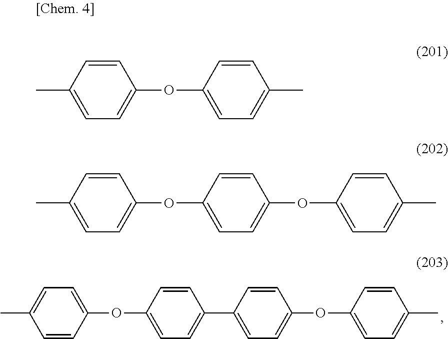
and n represents an integer of 0 to 12], wherein
a content ratio of the repeating unit (A) to a total amount of the repeating units (A) and (B) is 10 to 70% by mole, and
the polyimide film has a linear expansion coefficient of 55 ppm/K or less, a tensile strength of 125 MPa or more, and a break elongation of 15% or more.

2. The polyimide film according to claim 1, wherein the content ratio of the repeating unit (A) to the total amount of the repeating units (A) and (B) is 20 to 60% by mole.

3. An organic electroluminescent element comprising the polyimide film according to claim 1.

4. A transparent electro-conductive laminate comprising:
the polyimide film according to claim 1; and
a thin film made of an electro-conductive material and stacked on the polyimide film.

5. A touch panel comprising the transparent electro-conductive laminate according to claim 4.

6. A solar cell comprising the transparent electro-conductive laminate according to claim 4.

7. A display device comprising the transparent electro-conductive laminate according to claim 4.
